(19) United States
(12) Patent Application Publication
(10) Pub. No.: US 2016/0226438 A1
(43) Pub. Date: Aug. 4, 2016

(54) SOLAR MODULE WITH DIODE DEVICE FOR SHADING

(71) Applicant: SOLARIA CORPORATION, Fremont, CA (US)

(72) Inventors: Kevin R. GIBSON, Redwood City, CA (US); Adam DETRICK, Fremont, CA (US)

(21) Appl. No.: 14/869,130

(22) Filed: Sep. 29, 2015

Related U.S. Application Data
(63) Continuation-in-part of application No. 14/609,307, filed on Jan. 29, 2015.

(51) Int. Cl. H02S 40/34; H01L 31/05

(52) U.S. Cl. CPC H02S 40/34; H01L 31/0504

(57) ABSTRACT

In an example, a solar module apparatus is provided. The module has an equivalent diode device configured between the first end termination and the second end termination such that one of the plurality of photovoltaic strips associated with one of the plurality of strings when shaded causes the plurality of strips (“Shaded Strips”) associated with the one of the strings to cease generating electrical current from application of electromagnetic radiation, while a remaining plurality of strips, associated with the remaining plurality of strings, each of which generates a current that is substantially equivalent as an electrical current while the Shaded Strips are not shaded.

### CROSS REFERENCE TO RELATED APPLICATIONS

This application is a continuation in part of and claims priority to U.S. Ser. No. 14/609,307 filed Jan. 29, 2015 (Attorney Docket No. A906RO-018100US), commonly assigned, and hereby incorporated by reference herein.

### BACKGROUND OF THE INVENTION

The present invention is directed to photovoltaic systems and manufacturing processes and apparatus thereof. In particular, the present invention provides an apparatus and method for using diode protection for a high-density solar module.

As the population of the world has increased, industrial expansion has led to a corresponding increased consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

In addition to oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sunlight. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many desirable characteristics; it is renewable, clean, abundant, and often widespread. Certain technologies developed often capture solar energy, concentrate it, store it, and convert it into other useful forms of energy.

Solar panels have been developed to convert sunlight into energy. For example, solar thermal panels are used to convert electromagnetic radiation from the sun into thermal energy for heating homes, running certain industrial processes, or driving high-grade turbines to generate electricity. As another example, solar photovoltaic panels are used to convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successfully for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of costly photovoltaic silicon bearing wafer materials, which are often difficult to manufacture efficiently on a large scale, and sources can be limited.

Therefore, it is desirable to have novel system and method for manufacturing solar panels.

### BRIEF SUMMARY OF THE INVENTION

The present invention is directed to photovoltaic systems and manufacturing processes and apparatus thereof. In particular, the present invention provides an apparatus and method for using diode protection for a high-density solar module. There are other embodiments as well.

In an example, a solar module apparatus is provided. The apparatus has a plurality of strings, each of the plurality of strings being configured in a parallel electrical arrangement with each other and a plurality of photovoltaic strips forming each of the plurality of photovoltaic strings. The apparatus has a first end termination configured along a first end of each of the plurality of strings and a second end termination configured along a second end of each of the plurality of strings. The module has an equivalent diode device configured between the first end termination and the second end termination such that one of the plurality of photovoltaic strips associated with one of the plurality of strings when shaded causes the plurality of strips (“Shaded Strips”) associated with the one of the strings to cease generating electrical current from application of electromagnetic radiation, while a remaining plurality of strips, associated with the remaining plurality of strings, each of which generates a current that is substantially equivalent as an electrical current while the Shaded Strips are not shaded, and the equivalent diode device between the first terminal and the second terminal for the plurality of strips is configured to turn-on to by-pass electrical current through the equivalent diode device such that the electrical current that was by-passed traverses the equivalent diode device coupled to the plurality of strips that are configured parallel to each other.

Many benefits can be achieved by ways of the present invention. As an example, the present module can be made using conventional process and materials. Additionally, the present module is more efficient than conventional module designs. Furthermore, the present module, and related techniques provides for a more efficient module usage using by-pass diodes configured with multiple zones of solar cells. Depending upon the example, there are other benefits as well.

A further understanding of the nature and advantages of the present invention may be realized by reference to the remaining portions of the specification and the drawings.

### BRIEF DESCRIPTION OF THE DRAWINGS

FIG. 1 is a simplified diagram illustrating a conventional photovoltaic module.

FIG. 2 is a plot illustrating an I-V curve for the conventional photovoltaic module when a cell is shaded.

FIG. 3 is a plot illustrating an I-V curve for the conventional photovoltaic module all cells are un-shaded.

FIG. 4 is a simplified diagram illustrating a conventional photovoltaic module having a single cell shaded. The diagram also depicts the loss of the power contribution from the string that contains the shaded cell.

FIG. 5 is a plot illustrating an I-V curve for the conventional photovoltaic module depicted in FIG. 4.

FIG. 6 is a simplified diagram illustrating a conventional photovoltaic module having a single cell shaded in each string of solar cells. In this case all three stings in the module are bypassed and the module does not make any power.

FIG. 7 is a simplified diagram illustrating a photovoltaic module according to an example of the present invention.

FIG. 8 is a simplified diagram illustrating a photovoltaic module according to an example having a shaded strip of the present invention and the module does not have any bypass diodes.

FIG. 9 is a plot illustrating an I-V curve for a photovoltaic module in FIG. 9 according to an example of the present invention.

FIG. 10 is a simplified diagram illustrating a photovoltaic module according to an example having a shaded strip of the present invention and the bypass diodes.

FIG. 11 is a plot illustrating an I-V curve for a photovoltaic module in FIG. 11 according to an example of the present invention.

FIG. 12 is a simplified diagram illustrating a photovoltaic module according to an example having a group of shaded strips of the present invention.

FIG. 13 is a plot illustrating an I-V curve for a photovoltaic module in FIG. 13 according to an example of the present invention.

FIG. 14 is a simplified diagram illustrating a photovoltaic module according to an example having a group of shaded strips of the present invention in a different orientation from FIG. 12

FIG. 15 is a plot illustrating an I-V curve for a photovoltaic module in FIG. 14 according to an example of the present invention.

FIG. 16 is a simplified diagram illustrating a photovoltaic module according to an example having a group of shaded strips of the present invention in a different orientation from FIGS. 12 and 14

FIG. 17 is a plot illustrating an I-V curve for a photovoltaic module in FIG. 16 according to an example of the present invention.

FIG. 18 is a simplified diagram illustrating a photovoltaic module according to an example having almost all shaded strips of the present invention.

FIG. 19 is a plot illustrating an I-V curve for a photovoltaic module in FIG. 18 according to an example of the present invention.

FIG. 20 is a simplified diagram illustrating a photovoltaic module according to an example having all strips with both serial and parallel connections of the present invention.

FIG. 21 is a plot illustrating an I-V curve for a photovoltaic module in FIG. 20 when one strip is shaded according to an example of the present invention.

FIG. 22 is simplified diagram illustrating another embodiment of the current invention.

FIG. 23 is a simplified diagram illustrating one zone of a module. PV strips are shown in series, which make up a string. The illustration shows 6 strings in parallel. All parallel strings and the PV strips in each of the strings are protected by one diode.

FIG. 24 is a simplified diagram illustrating a standard solar module, a high density solar module, and a high density module according to an example of the present invention, which is configured in vertical strips, as shown.

FIG. 25 is a simplified illustration of the aforementioned high density module configured on a solar tracker according to an example of the present invention.

FIG. 26 is a simplified illustration of a solar module configured with diode protection for sixty nine strips in series, twenty three strip substrings, and three substrings in series for a module according to an example of the present invention.

FIG. 27 is a simplified illustration of shading on a lower one third of a solar module according to an example of the present invention.

FIG. 28 is a simplified illustration of shading on a lower one third of a solar module using a shortened string on a lower portion of the solar module according to an example of the present invention.

FIG. 29 is a simplified illustration of a diode protection configuration for a shortened string on a lower portion of the solar module according to an example of the present invention.

FIG. 30 is a simplified illustration of a solar module, including front view, side view, back view, perspective views according to examples of the present invention.

FIG. 31 is an expanded view of a solar module according to an example of the present invention.

FIG. 32 is a simplified illustration of a front view, including an expanded region, of a solar module according to an example of the present invention.

FIG. 33 is a simplified illustration of a diode configuration for a solar module according to an example of the present invention.

### DETAILED DESCRIPTION OF THE INVENTION

The present invention is directed to photovoltaic systems and manufacturing processes and apparatus thereof. There are other embodiments as well.

Embodiments of the present invention provide system and methods for manufacturing high density solar panels. Embodiments of the present invention use overlapped or tiled photovoltaic strip elements to increase the amount of photovoltaic material, thereby increasing an amount of power, while reducing an amount of series resistance losses in the solar panel. It is noted that specific embodiments are shown for illustrative purposes, and represent examples. One skilled in the art would recognize other variations, modifications, and alternatives.

Although orientation is not a part of the invention, it is convenient to recognize that a solar module has a side that faces the sun when the module is in use, and an opposite side that faces away from the sun. Although, the module can exist in any orientation, it is convenient to refer to an orientation where “upper” or “top” refer to the sun-facing side and “lower” or “bottom” refer to the opposite side. Thus an element that is said to overlie another element will be closer to the “upper” side than the element it overlies.

While the above is a complete description of specific embodiments of the invention, the above description should not be taken as limiting the scope of the invention as defined by the claims.

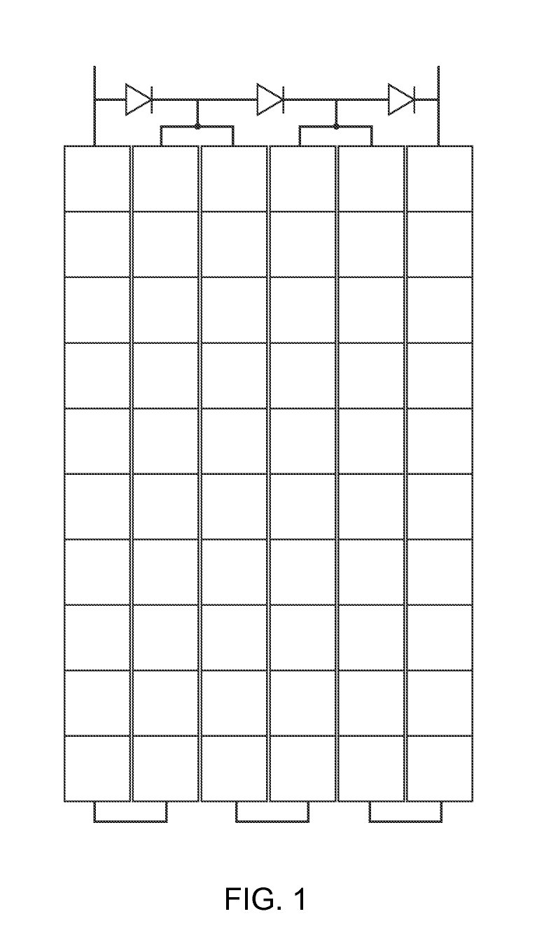

FIG. 1 is a simplified diagram illustrating a conventional photovoltaic module. This representative module consists of 60 photovoltaic cells in series. Each solar cell is illustrated by the square shaped article. Each of which is coupled with each other. There are three zones in the module each protected by a bypass diode. The bypass diode is commonly a Shottky diode, which will be further described below. Each zone is illustrated by a pair of columns of solar cells. Each pair corresponding to a particular zone is protected by the bypass diode. Typically this module would be approximately 1.6 m in length and 1.0 m in width. As shown, each of the cells is connected in series with each other.

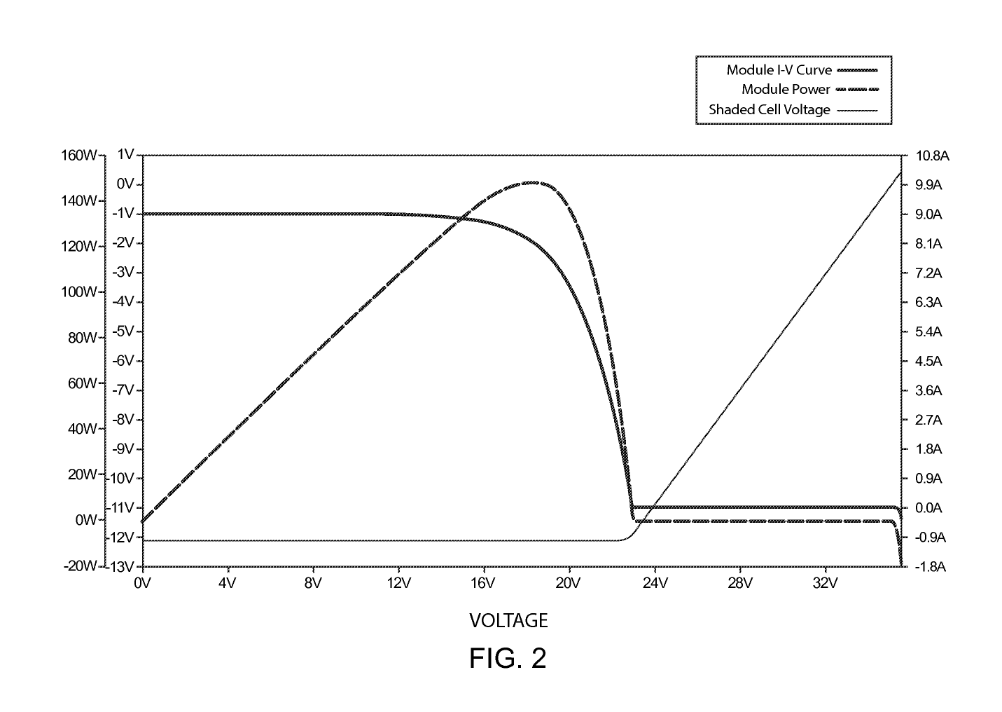

FIG. 2 is a plot illustrating an I-V curve for the conventional photovoltaic module. When a particular cell is shaded in the conventional module. The bypass diode limits the reverse voltage on the shaded cell below the reverse voltage breakdown of the solar cell. This inhibits the shaded cell from developing a hot spot. As shown in the diagram, the reverse voltage is limited to about −12V.

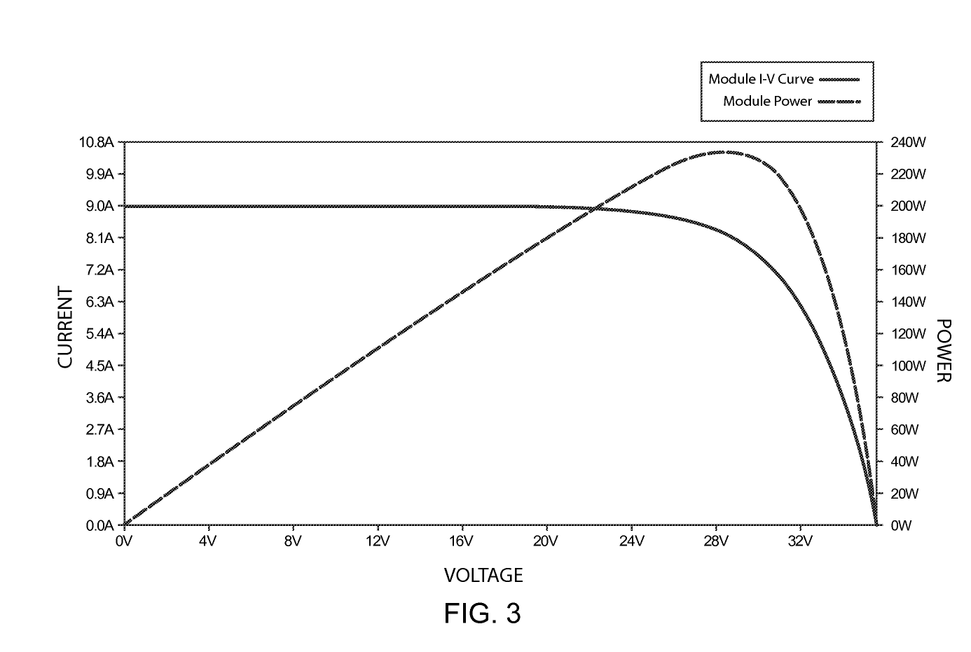

FIG. 3 is a plot illustrating an I-V curve for the conventional photovoltaic module without any shading. As illustrated, the maximum power of the module is about 240 W.

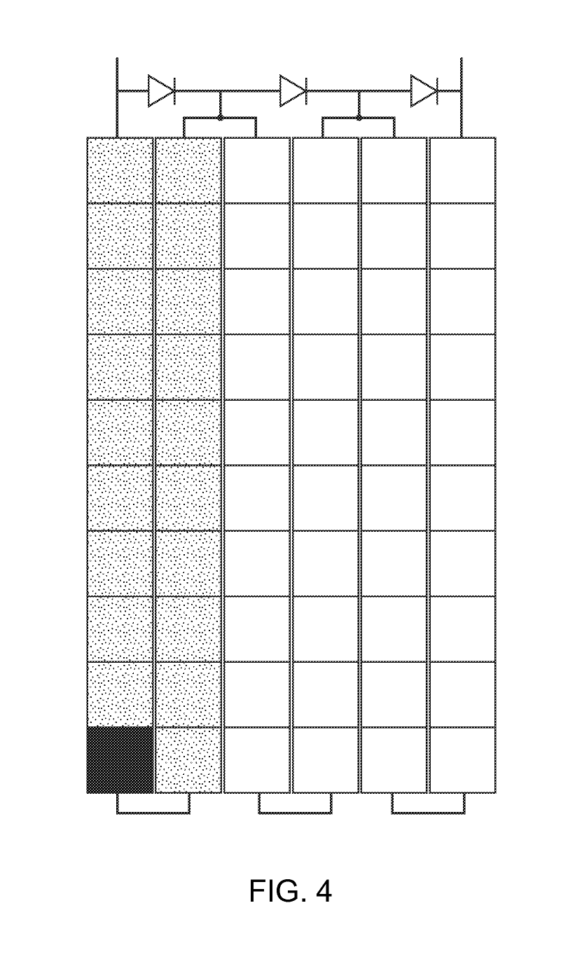

FIG. 4 is a simplified diagram illustrating a conventional photovoltaic module having a single cell shaded. As shown when the single cell is shaded, the remaining cells in the same string as the shaded cell cease to contribute power to the module even though they are not shaded. These cells are highlighted by light shading. That is, the single shaded cell leads to a reduction of one third of the power output of the conventional solar cell.

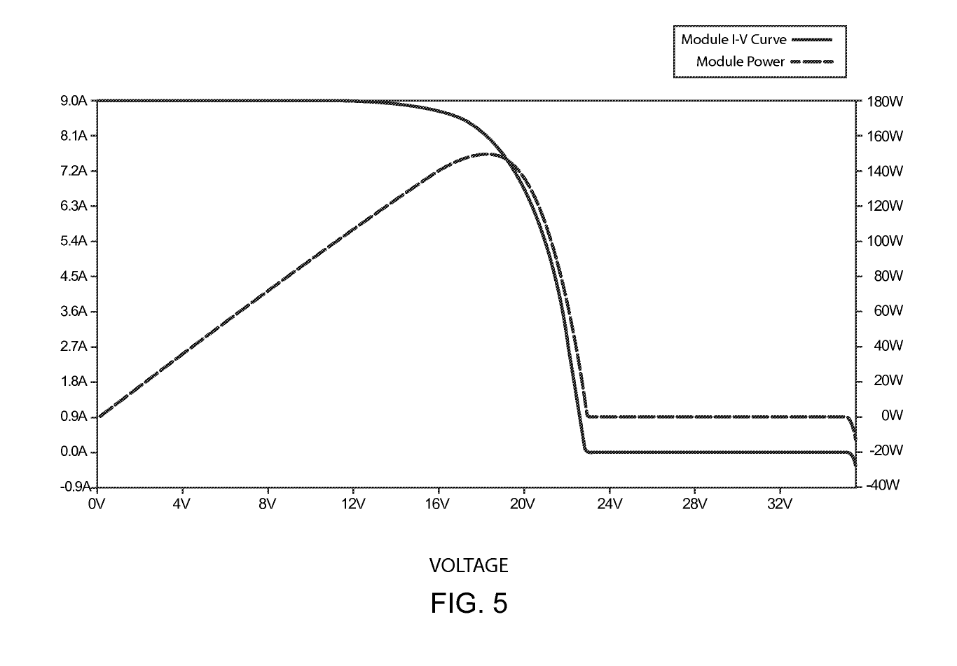

FIG. 5 is a plot illustrating an I-V curve for the conventional photovoltaic module with a shaded cell as shown in FIG. 4. If the maximum power for a module is 240 W as shown in FIG. 3, then when there is one shaded cell, the module loses about one third (⅓) of it power generating capacity, as noted. That is, shading the single cell leads to a significant reduction in power output of the conventional solar cell.

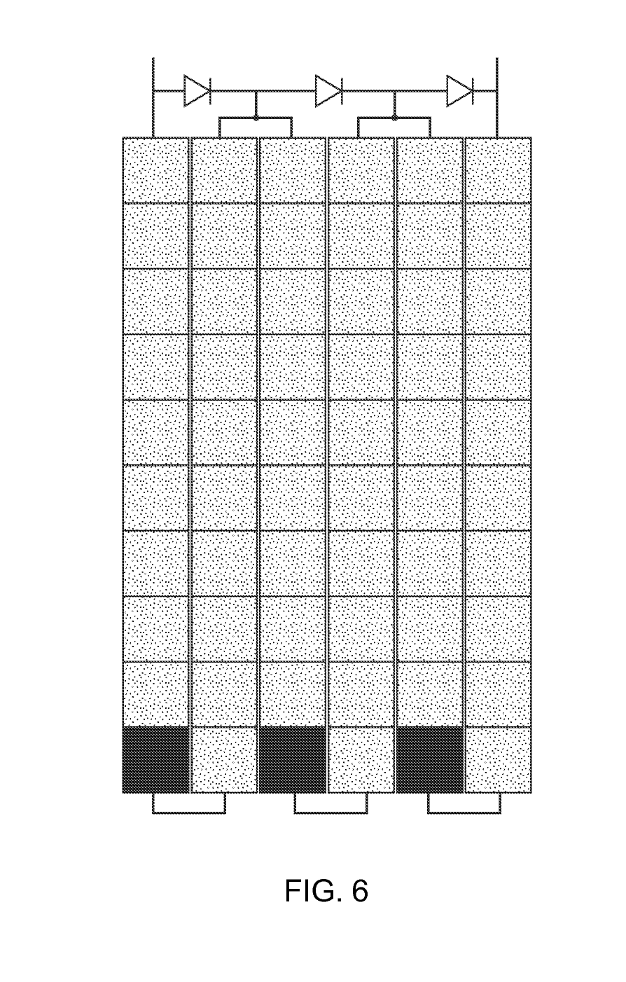

FIG. 6 is a simplified diagram illustrating a conventional photovoltaic module having a single cell shaded in each string of solar cells in the module. As shown, a single cell shaded in each string leads to a complete reduction of power generation of an entirety of the solar module. That is, this will inhibit the module from producing any power in the solar module, which would lead to a completely inefficient module.

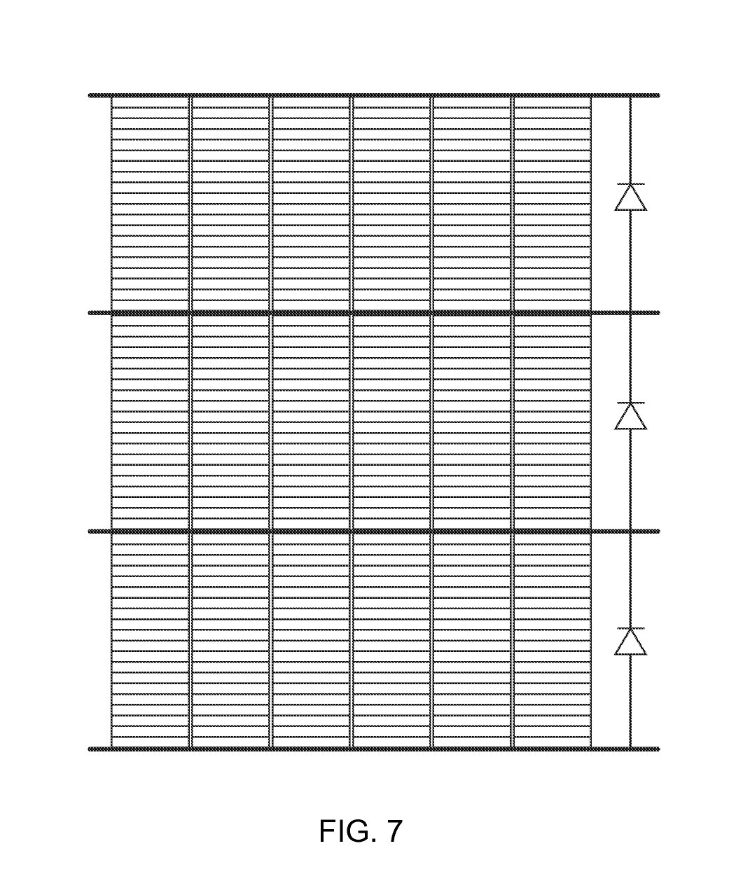

FIG. 7 is a simplified diagram illustrating a photovoltaic module according to an example of the present invention. As shown, the module has the same amount of photovoltaic (“PV”) material, although there may be variations, as the module shown in FIG. 1. In this case, the PV cells in FIG. 1 were made into five (5) PV strips. The PV strips are then fabricated into strings of twenty (20) cells. In an example, six strings are connected in parallel and protected by one bypass diode. This zone of parallel stings is then interconnected with another group of six (6) parallel strings protected by its own bypass diode. FIG. 7 depicts three (3) zones but there could be many more in other examples.

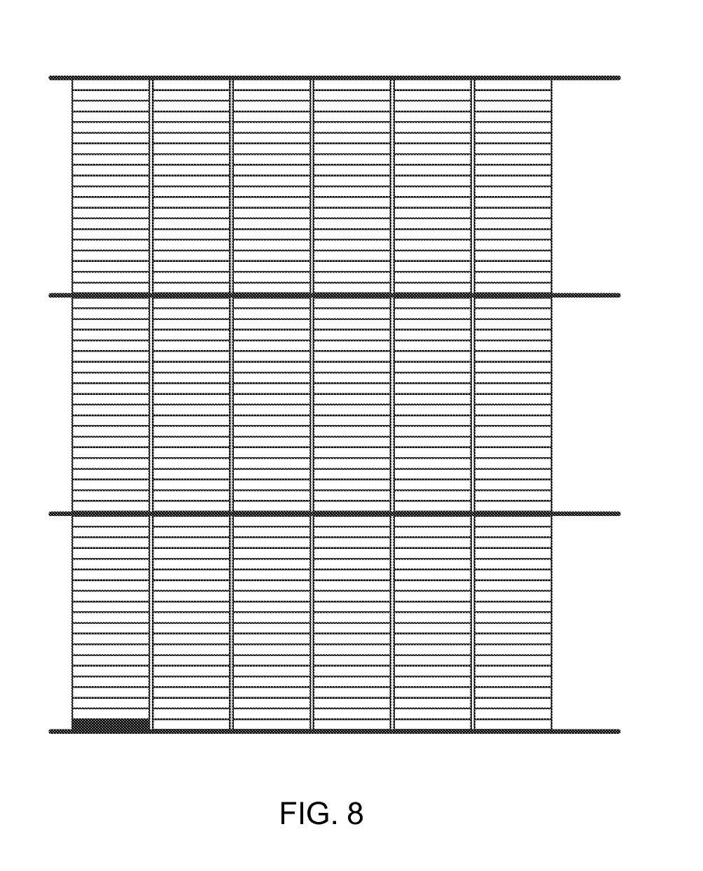

FIG. 8 is a simplified diagram illustrating a photovoltaic module according to an example having a shaded strip of the present invention without bypass diodes in the module.

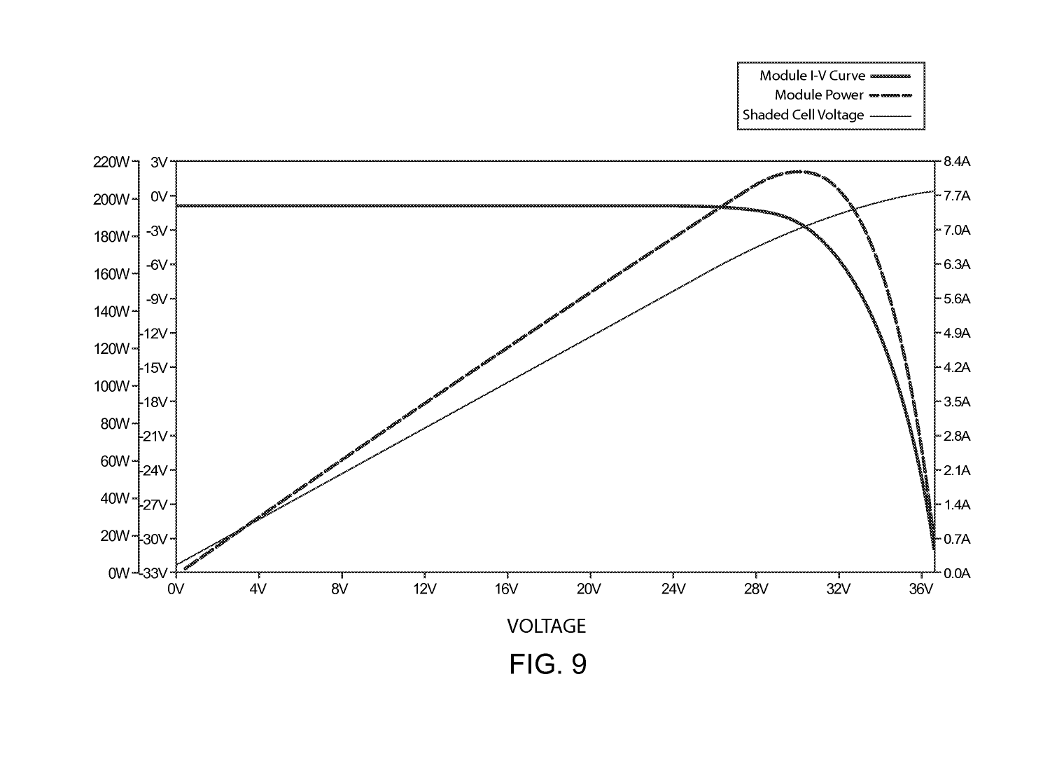

FIG. 9 is a plot illustrating an I-V curve for the photovoltaic module in FIG. 8 according to an example of the present invention. The shaded cell voltage graph shows that when the module is in a short circuit condition, it is possible for the shaded cell to have almost −33V, far exceeding the reverse bias breakdown of the PV strip.

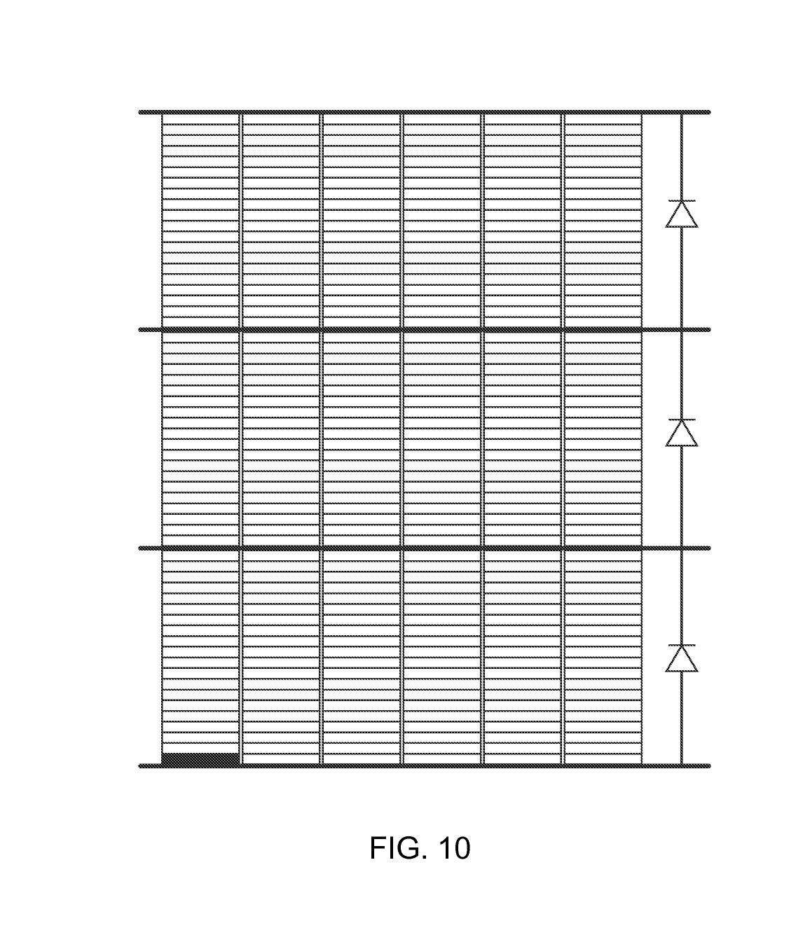

FIG. 10 is a simplified diagram illustrating a photovoltaic module according to an example having a shaded strip of the present invention with bypass diodes in the module.

In an example, a solar module is shown. The module has an array of solar cells. The array can be N by M, where N is an integer of 1 and greater and M is an integer of 2 and greater. In an example, the module has a plurality of zones dividing the array of solar cells. In an example, the zones are numbered from 1 through R, where R is 4 and greater. Each of the plurality of zones is in series with each other in an example. As shown, the solar module has three zones each of which is connected to each other in series.

As shown, the module has a plurality of photovoltaic strings dividing each of the plurality of zones. Each of the plurality of photovoltaic strings is in parallel with each other. In an example, the plurality of photovoltaic strings are numbered, respectively, from 2 to 12. As shown in this example, each zone has six strings, which are coupled to each other.

As shown, the module has a plurality of photovoltaic strips forming each of the plurality of photovoltaic strings. As shown, the plurality of strips range in number from 2 to 30. Each of the plurality of strips is configured in a series arrangement with each other.

As also shown, a first bus bar and a second bus bar are configured on each of the zones of the solar cells. In this example, four (4) bus bars are illustrated. A first and second bus bar are configured to the first zone. The second and a third bus bar are configured to a second zone.

The third and a four bus bar are configured to the third zone. As used herein, the terms “first” “second” “third” or “fourth” do not necessarily imply order, and should be interpreted under ordinary meaning. In an example, an equivalent diode device is configured between the first bus bar and the second bus bar for a particular zone. Each zone has an equivalent diode device, as shown.

As shown, one of the plurality of photovoltaic strips associated with one of the plurality of strings and associated with a first plurality of zones is shaded. The one shaded strip causes the plurality of strips (“Shaded Strips”) associated with the one of the strings to cease generating electrical current from application of electromagnetic radiation associated one of the strings. All of the remaining plurality of strips, associated with the remaining plurality of strings in the zone, each of which generates a current that is substantially equivalent as the current while the Shaded Strips are not shaded. The diode device between the first bus bar and the second bus bar for the plurality of strips is configured to turn-on to by-pass electrical current from the Shaded Strips through the diode device and the electrical current that was by-passed traverses an equivalent diode device coupled to the plurality of strips associated with a second plurality of zones.

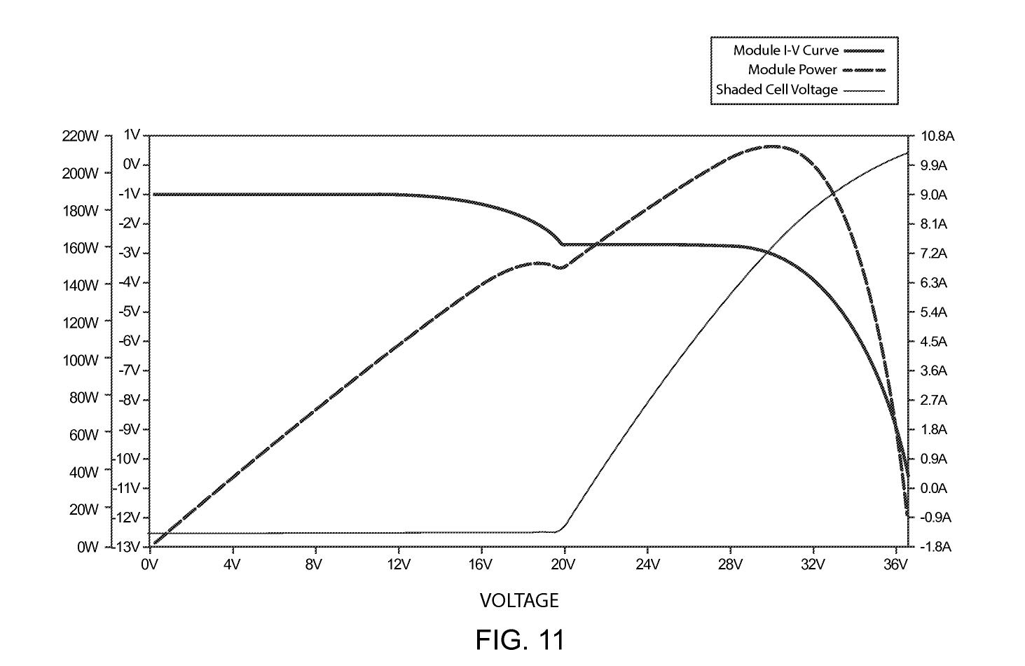

FIG. 11 is a plot illustrating an I-V curve for a photovoltaic module in FIG. 10 according to an example of the present invention. The figure shows that the reverse bias voltage across the shaded cell when in a short circuit condition is limited to about −12.5V. This is below the threshold for reverse voltage breakdown for the shaded solar cell. The diode protects the shaded cell in the string when the string is in parallel with other stings.

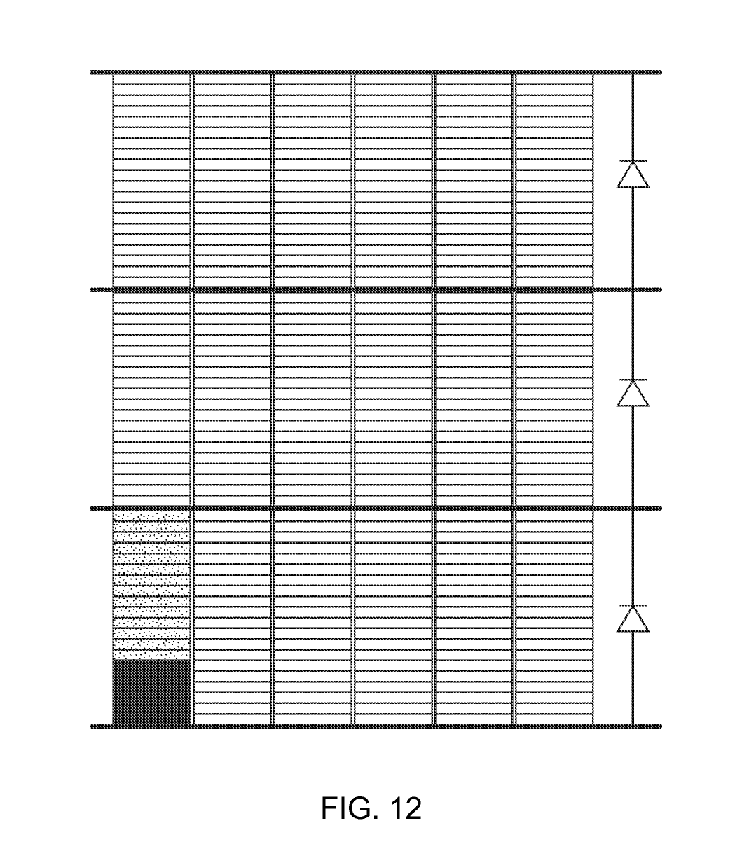

FIG. 12 is a simplified diagram illustrating a photovoltaic module according to an example having a group of shaded strips of the present invention The active photovoltaic area of the module and location being shaded is identical to the convention solar module in FIG. 4. However, the module efficiency is much higher in this present example, as will be shown throughout the present specification and more particularly below.

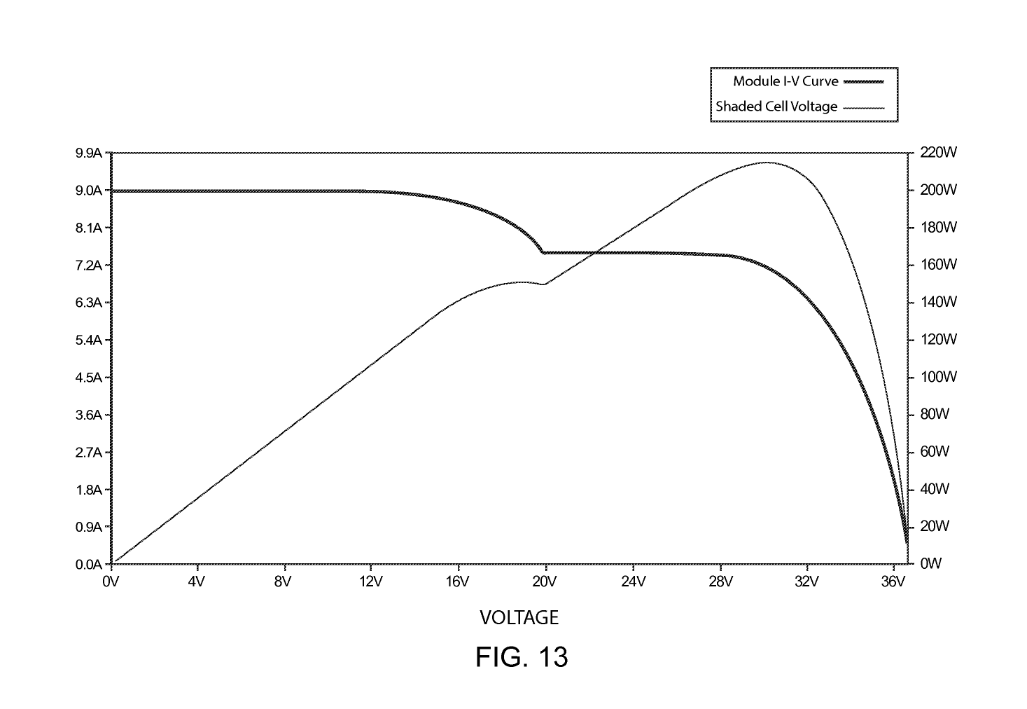

FIG. 13 is a plot illustrating an I-V curve for the photovoltaic module in FIG. 12 according to an example of the present invention. The maximum module power is reduced by about 1/18 of the maximum power of the unshaded module in FIG. 7 as shown by the IV curve in FIG. 13. In this case the illustration of the present invention had much less shading losses than the conventional module in FIG. 4. The conventional module lost ⅓ of its generating capacity with the equivalent amount of shading.

As shown, six of the plurality of photovoltaic strips associated with one of the plurality of strings and associated with a first plurality of zones is shaded. The shaded strips causes the plurality of strips (“Shaded Strips”) associated with the one of the strings to cease generating electrical current from application of electromagnetic radiation associated one of the strings. All of the remaining plurality of strips, associated with the remaining plurality of strings in the zone, each of which generates a current that is substantially equivalent as the current while the Shaded Strips are not shaded. The diode device between the first bus bar and the second bus bar for the plurality of strips is configured to turn-on to by-pass electrical current from the Shaded Strips through the diode device and the electrical current that was by-passed traverses an equivalent diode device coupled to the plurality of strips associated with a second plurality of zones.

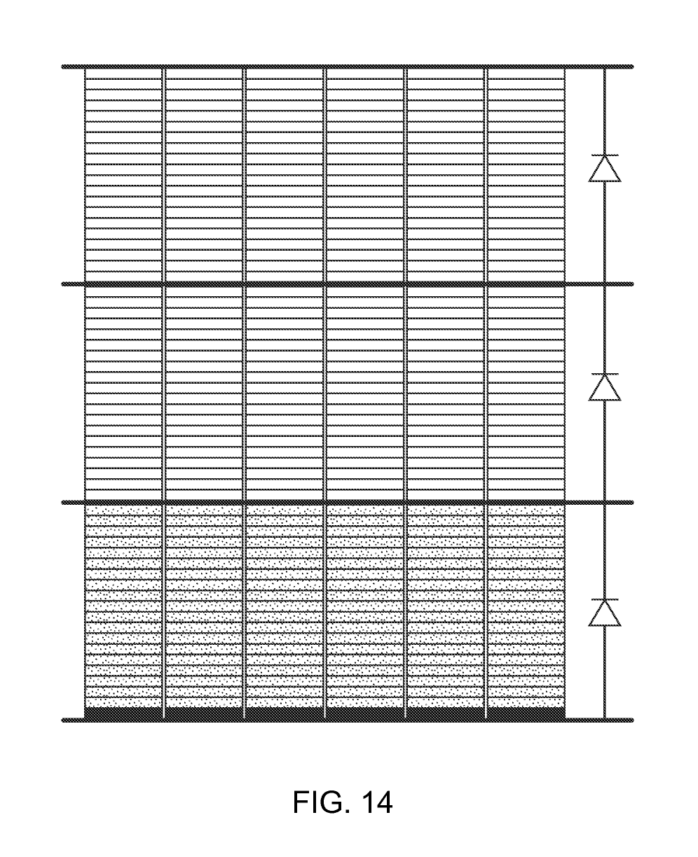

FIG. 14 is a simplified diagram illustrating a photovoltaic module according to an example having shaded strips of the present invention where the bottom of the module is shaded. In this case, all six parallel string will cease to produce power The remaining 12 strings in the module will continue to produce power. This example is a similar shading condition as depicted in FIG. 6 of the conventional module. However, the conventional module will cease producing any power while the module with the present invention will only lose only ⅓ of its power generating capability.

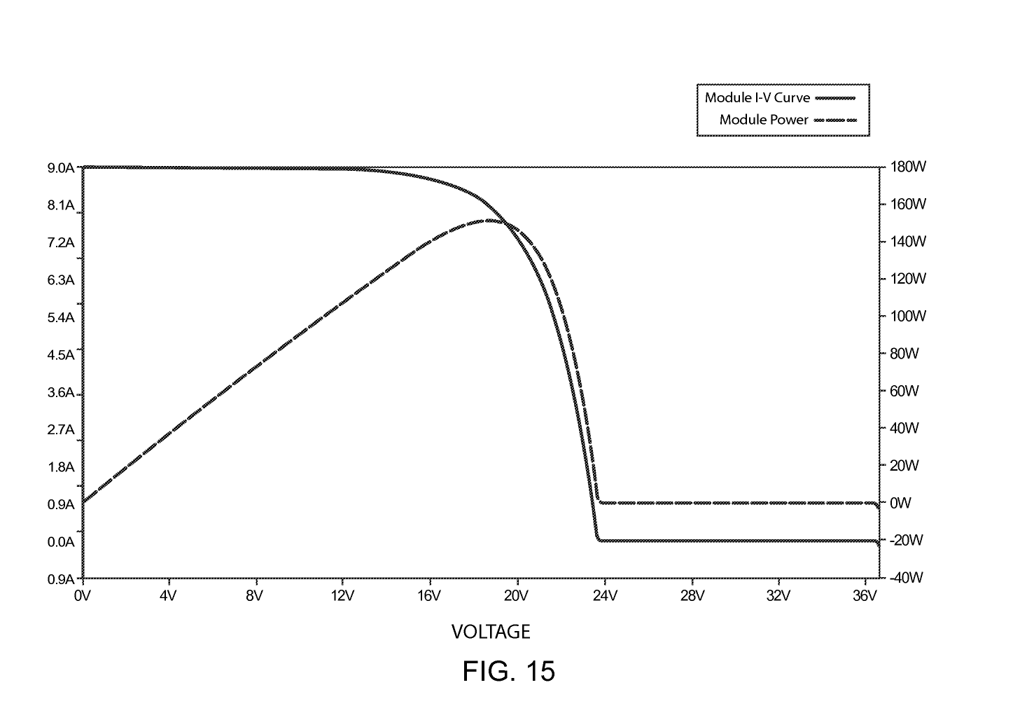

FIG. 15 is a plot illustrating an I-V curve for a photovoltaic module according to an example of the present invention. It depicts the power production of the module when shaded as shown in FIG. 14.

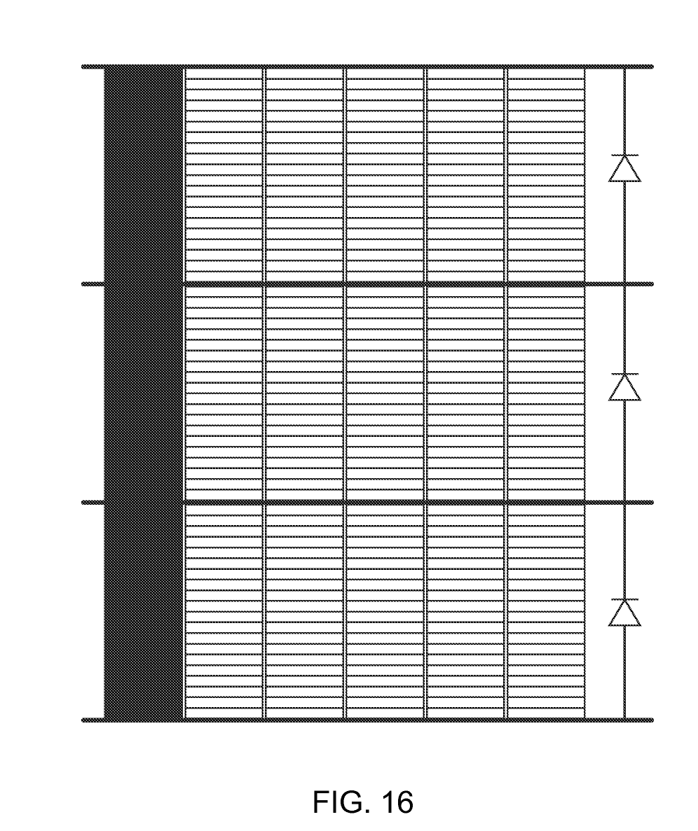

FIG. 16 is a simplified diagram illustrating a photovoltaic module according to an example of the present invention having shaded strips along the length of the module. As shown, a string is shaded in each of the zones, which are in serial arrangement with each other.

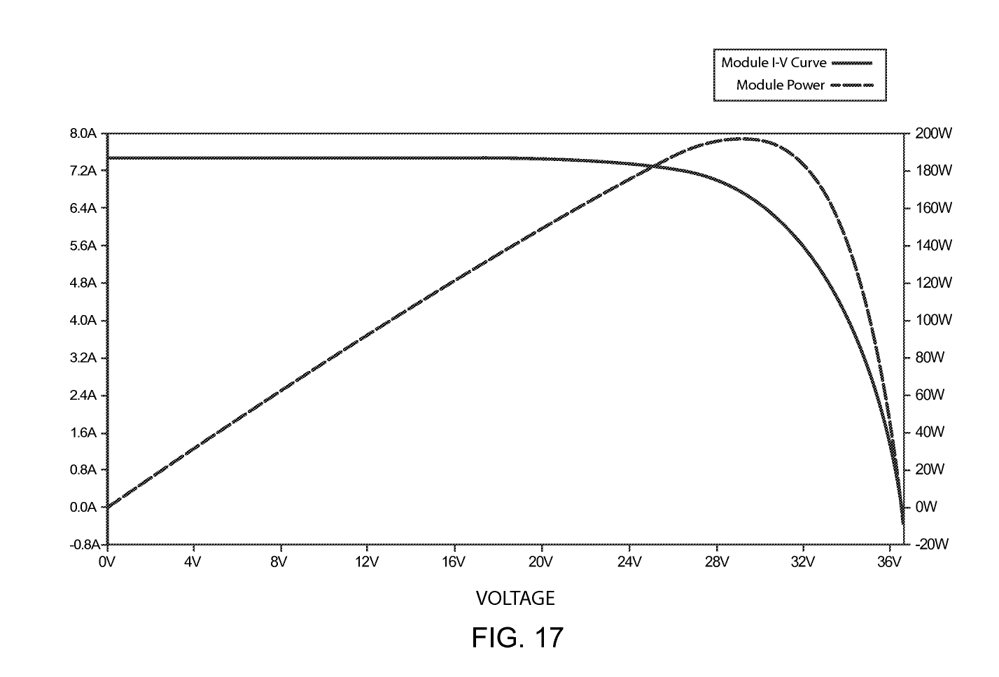

FIG. 17 is a plot illustrating an I-V curve for a photovoltaic module according to an example of the present invention when shaded as depicted in FIG. 16. This IV curve shows the maximum power production of the module at about ⅚^{th} of the maximum power production of the module in an unshaded condition. This is better than the conventional module that will have only ⅔^{rd} of the maximum power production in similar shading conditions compared to the conventional module without shading.

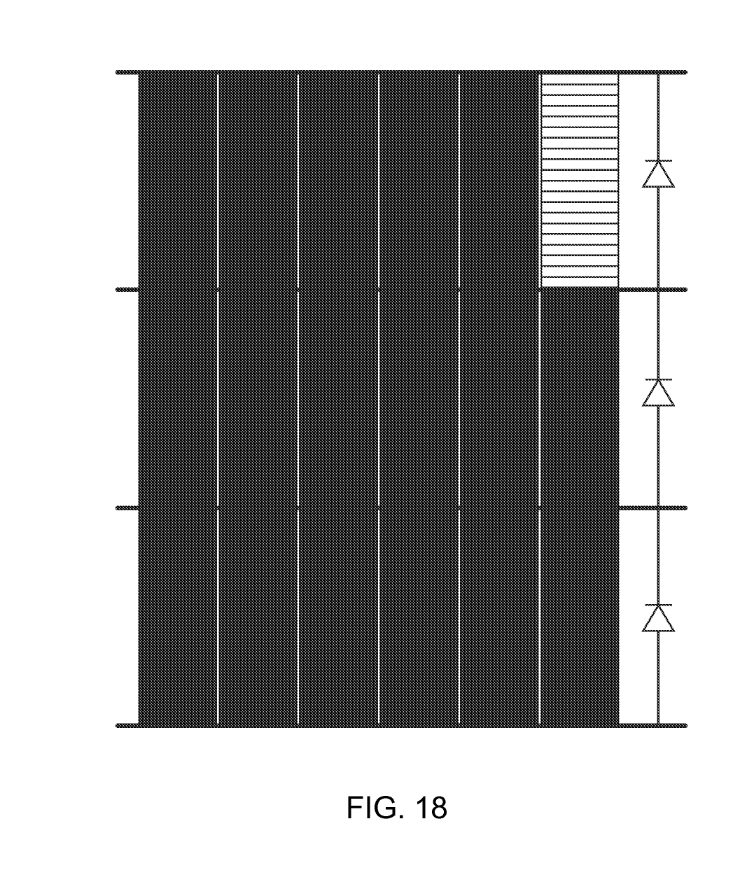

FIG. 18 is a simplified diagram illustrating a photovoltaic module according to an example of the present invention where 17/18^{th} of the module is shaded.

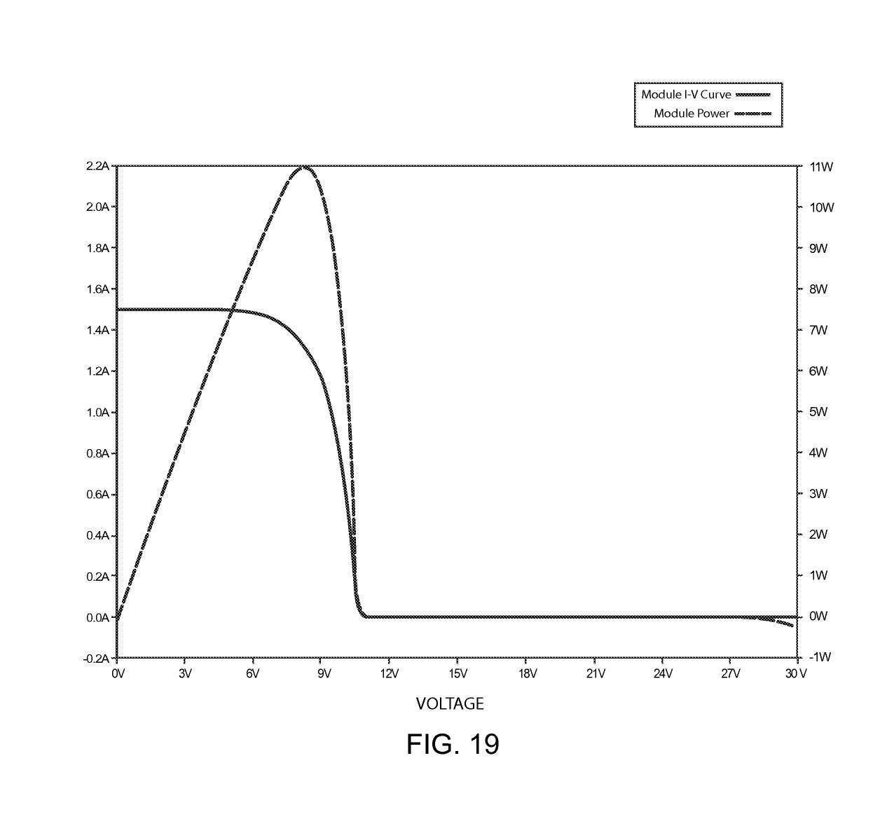

FIG. 19 is a plot illustrating an I-V curve for a photovoltaic module according to an example of the present invention in FIG. 19. It shows that the module is still capable of producing power while the conventional module would not be able to produce any power.

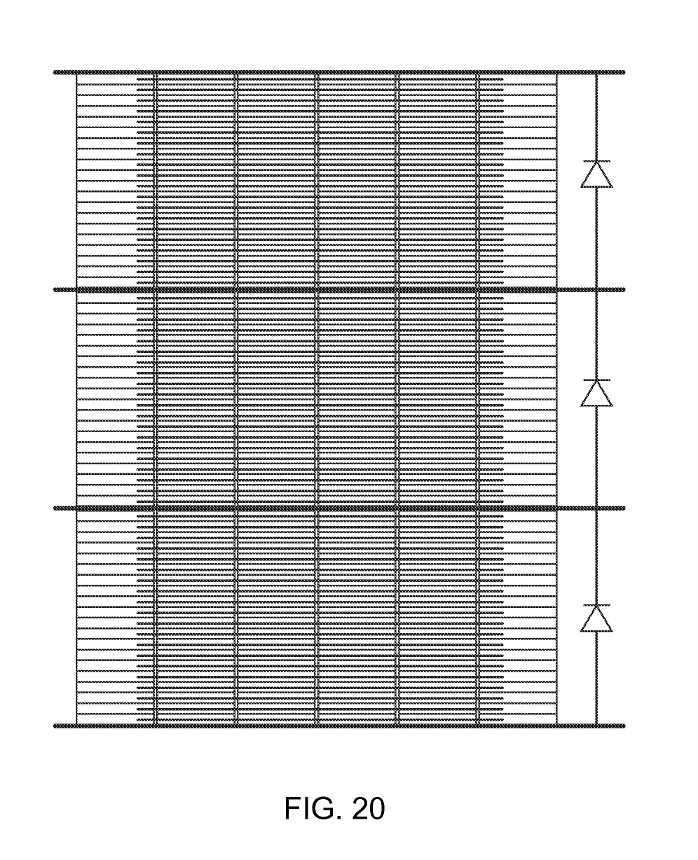

FIG. 20 is a simplified diagram illustrating a photovoltaic module according to an example of another embodiment of the invention in which all cells are in series and in parallel with the neighboring cells. In an example, the module also has a plurality of electrical strings. Each of the strings is an electrical conducive member. Each of the electrical stings is configured to form an equivalent strip provided by a plurality of strips, which are arranged in parallel to each other, from a plurality of stings connected in parallel to each other, as shown.

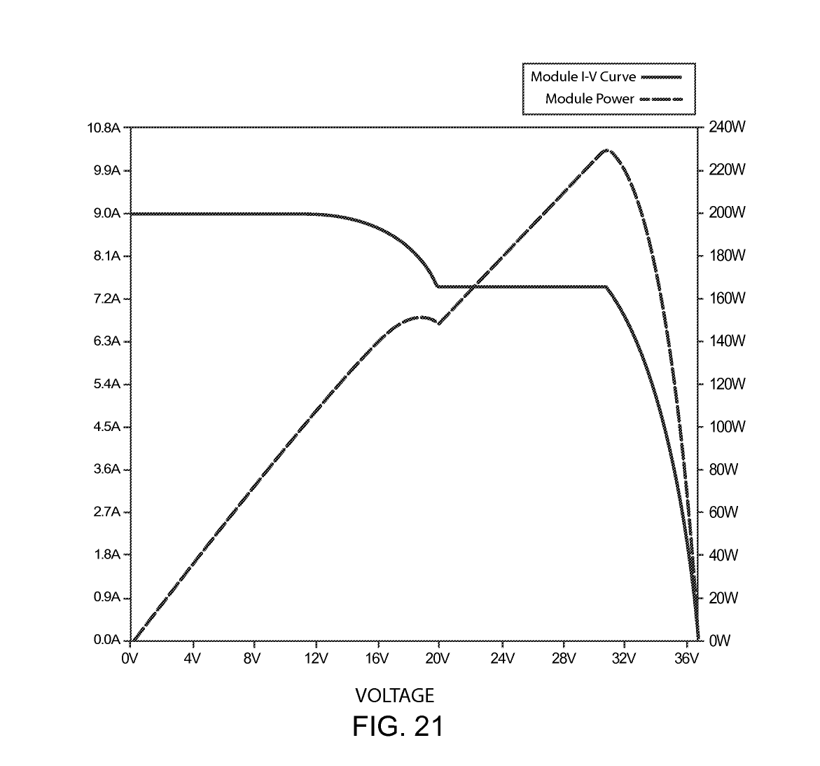

FIG. 21 shows plots illustrating an I-V curve for a photovoltaic module according to an example of the present invention. When a photovoltaic (“PV”) strip is shaded the module will only decrease power production by the individual strip. The rest of the PV strips in the same string as the shaded strip will be able to produce power as will the un-shaded strings in the module.

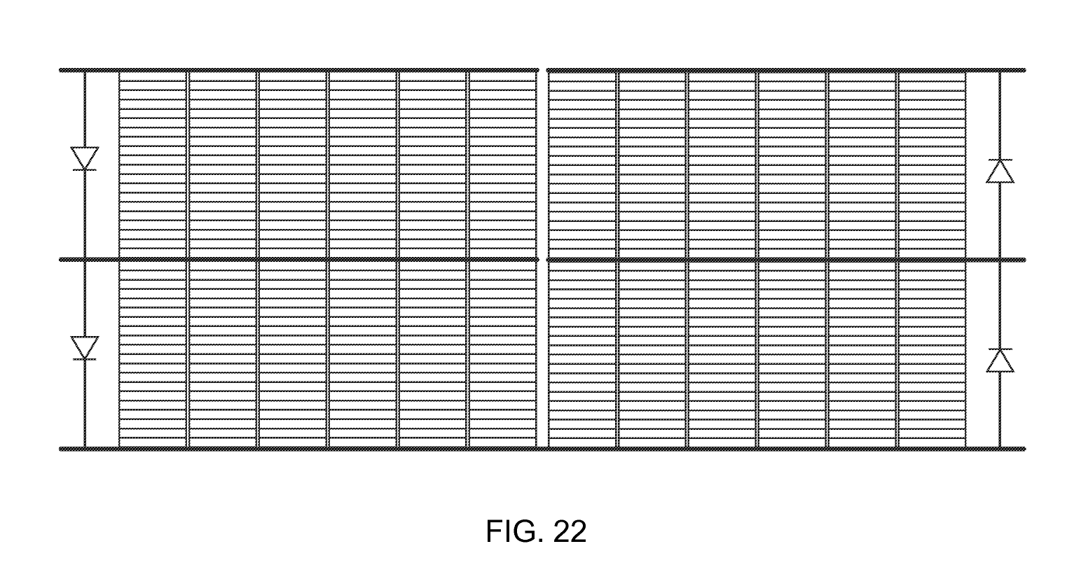

FIG. 22 is simplified diagram illustrating another embodiment of the current invention. The physical orientation of the strings is different but electrically the layout is similar. FIG. 22 illustrates a module that contains four (4) zones. Each zone is configured and protected by a by-pass diode device. A pair of zones is configured on one side of the array, as shown, to form a two by two array of zones, although there can be variations. Each zone has a plurality of strings configured in parallel arrangement with each other. Each string has a plurality of strips in an example.

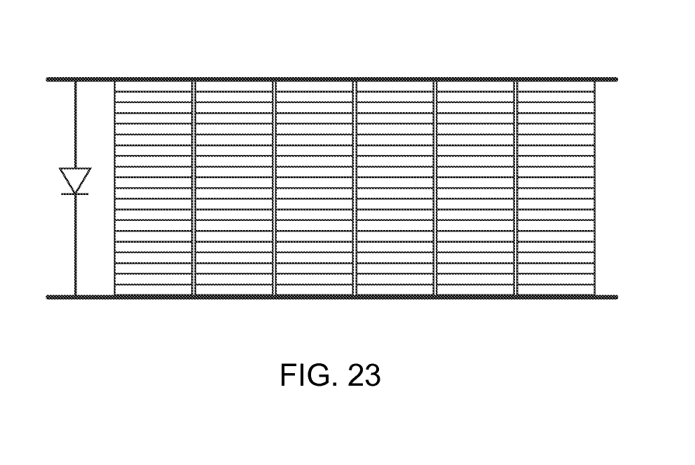

FIG. 23 is a simplified diagram illustrating one zone of a module. PV strips are shown in series, which make up a string. The illustration shows six (6) strings in parallel. All parallel strings and the PV strips in each of the strings are protected by one diode.

In an example, the plurality of strings can be numbered from 2 to 12, while six is shown in this illustration. Each of the plurality of strings is configured in a parallel electrical arrangement with each other. In an example, the plurality of photovoltaic strips forms each of the plurality of photovoltaic strings. The plurality of strips can range from 2 to 30 such that each of the plurality of strips is configured in a series arrangement with each other. In an example, the zone has a first end termination configured along a first end of each of the plurality of strings. In an example, the first end termination is a first terminal. In an example, the second end termination is configured along a second end of each of the plurality of strings. In an example, the second end termination is a second terminal.

In an example, an equivalent diode device is configured between the first end termination and the second end termination such that one of the plurality of photovoltaic strips associated with one of the plurality of strings when shaded causes the plurality of strips (“Shaded Strips”) associated with the one of the strings to cease generating electrical current from application of electromagnetic radiation. All of the remaining plurality of strips, associated with the remaining plurality of strings, each of which generates a current that is substantially equivalent as an electrical current while the Shaded Strips are not shaded. The equivalent diode device between the first terminal and the second terminal for the plurality of strips is configured to turn-on to by-pass electrical current through the equivalent diode device such that the electrical current that was by-passed traverses the equivalent diode device coupled to the plurality of strips that are configured parallel to each other. In an example, the plurality of strings is provided in a zone. As previously noted, one zone is among a plurality of zones to form the solar module.

In an example, the solar module is configured to generate from 100 to 600 Watts. Also, the equivalent diode characterized as a plurality of individual diode devices each of which protects a string among the plurality of strings. Of course, there can also be other variations, alternatives, and modifications.

In an example, the equivalent diode device is a sum of individual diode devices coupled to each of the plurality of strips in each of the plurality of strings in each zone.

In an example, each of the plurality of strips comprises a thickness of photovoltaic material comprising a front bus bar and a back bus bar. In an example, the front bus bar is provided along a first edge region and the back bus bar being provided along a second edge region.

In an example, each of the plurality of strips comprises a thickness of photovoltaic material comprising a front bus bar and a back bus bar. In an example, the front bus bar is provided along a first edge region and the back bus bar being provided along a second edge region. In an example, each of the plurality of strips is associated with one of the plurality of strings. In an example, each of the plurality of strings is associated with one of the plurality of strings being in an overlapped configuration to physically and electrically configure the string.

In an example, each of the plurality of strips comprises a thickness of photovoltaic material comprising a front bus bar and a back bus bar. In an example, the front bus bar is provided along a first edge region and the back bus bar being provided along a second edge region. In an example, each of the plurality of strips is associated with one of the plurality of strings. In an example, each of the plurality of strings associated with one of the plurality of strings being in an overlapped configuration to physically and electrically configured to the string. In an example, each of the plurality of strips is configured from a silicon based mono-crystalline or multi-crystalline solar cell.

In an example, the array of solar cells configured to generate 300 to 450 Watts. In an example, each of the zones is configured to generate at least 70 Watts. In an example, each of the strips is configured to generate at least 0.8 Watt.

In an example, the module further comprising a pair of substrate members configured to sandwich the array of solar cells, at least one of the substrate members being a transparent material. In an example, the array of solar cells is operable at a maximum power of the array of solar cells minus a power amount associated with the Shaded Strips.

In an example, the module further comprising a power output equivalent to a maximum power rating less an amount equivalent to the string associated with the Shaded Strips. In an example, the module further comprising a power output equivalent to a maximum power rating less an amount equivalent to more the one of the strings associated with the Shaded Strips. In an example, the module further comprising a plurality of electrical strings, each of the electrical stings being configured to form an equivalent strip provided by a plurality of strips from a plurality of stings connected in parallel to each other.

Further details of a tiled or shingled photovoltaic strip arrangement can be found in U.S. Design Application No.: 29/509,179, filed Nov. 14, 2014, titled “TILED SOLAR CELL DESIGN,” (Our File No.: A906RO-018000US), commonly owned, and hereby incorporated by reference herein. Each of the strips is configured as a rectangular shape free from any visible and separate bus-bars. Of course there can be variations.

In an example, the solar apparatus is configured as parallel array of photovoltaic strips. The apparatus has a first array of photovoltaic strips. In an example, the first array is defined by one photovoltaic strip by n strips. In an example, the plurality of photovoltaic strips are arranged in series in an edge connected configuration and configured in tiled manner and/or layered manner and/or off-set stacked manner. In an example, the apparatus has a second array of photovoltaic strips. The second array is defined by one photovoltaic strip by n strips. In an example, the plurality of photovoltaic strips are arranged in series in an edge connected configuration and configured in a tiled manner and/or layered manner and/or off-set stacked manner. The apparatus has a first electrode member coupling a positive contact region of each of the first array of photovoltaic strips and the second array of photovoltaic strips and a second electrode member coupling a negative contact region of each of the first array of photovoltaic strips and the second array of photovoltaic strips. The apparatus has a diode device configured to the first electrode member and the second electrode member. The first array and the second array are configured to form a parallel string of photovoltaic strips.

In an example, the apparatus has a third array of photovoltaic strips. The third array is defined by one photovoltaic strip by n strips. In an example, the plurality of photovoltaic strips are arranged in series in an edge connected configuration; and a fourth array of photovoltaic strips. The fourth array is defined by one photovoltaic strip by n strips. In an example, the plurality of photovoltaic strips are arranged in series in an edge connected configuration. The first electrode member coupling a positive contact region of each of the third array of photovoltaic strips and the fourth array of photovoltaic strips; and the second electrode member coupling a negative contact region of each of the third array of photovoltaic strips and the fourth array of photovoltaic strips. The first array, the second array, the third array, and the fourth array are configured to form a parallel string of photovoltaic strips.

In an example, each of the photovoltaic strips comprises a width, a length, and a thickness, each of the photovoltaic strips comprising a first contact region and a second contact region. Each of the strips is configured on opposite edges of each other. The first contact region is along a top side of a first edge and the second contact region is along a bottom side of a second edge, which is on the opposite spatial side of the first edge. In an example, the first contact region comprises a first side region having an aluminum bus bar member, while an opposite has no aluminum material.

In an example, the equivalent diode device can be Schottky Barrier Rectifiers By-Pass Diode, or others. The device can have a 20SQ040, “Bypass Diodes for Solar Modules—Schottky Barrier Rectifiers Bypass,” manufactured by Dioden, Lite-on Semiconductor Corp, or others. In an example, the equivalent diode device is a metal of silicon rectifier, majority carrier conduction, has a guard ring for transient protection, low power loss, high efficiency, high surge and current capability, low VF, among other features. The diode is configured to a JEDEC R-6 molded plastic. The diode has a low forward voltage drop of 0.4V to 0.6V, and a maximum DC blocking voltage of 40-45V. Other features are included in a data sheet of such diode by either Lite-on Semiconductor Corp, or others, which are incorporated by reference herein.

In an example, the present invention provides a longer solar module and related methods. One or more of the following benefits and/or features can achieved:
1. Narrower module fits on a tracker properly
2. Voltage low (e.g., 45V) and the current high (e.g., 10 A) to reduce system costs;
3. Configuring the diode protection to minimize soiling shading losses, which will be further described below;
4. Minimize the effects of uneven illumination from tracker inter-row shading

Further details of the aforementioned features can be found throughout the present specification and more particularly below.

In an example, the present module has an increased size relative to standard solar modules. With traditional 156 mm cells, a larger module can be obtained by making the module longer or wider. Increasing the module size is a challenge in either direction. If the module gets longer by one cell, then the module has to grow by 156 mm. Now, instead of 24 cells per diode it will become 26. This is not usually possible because the reverse bias breakdown voltage of the cell will be exceeded during shading conditions, which will require implanting a costly diode scheme.

If the module were to become wider, it would have to become wider by 156×2 mm. This is because most modules have a loop that is 12 cells by 2 rows. This is needed so that the diode wiring stays simple. It is possible to make it one cell wider but it is still a 156 mm step. Many times single axis horizontal trackers, like the NEXTracker SPT manufactured by NEXTracker, Inc., have a defined width in which they can mount modules. In the NEXTracker case the optimal width is between 990 mm and 1010 mm per module. This allows 8 modules to be mounted on a single segment. If the module width increases, then either only 7 modules will fit on the tracker or the tracker will have to be redesigned to be wider. In either case the cost of the tracker would go up.

In an alternative example, the present module is configured to be longer than conventional. Beyond the diode problems that were highlighted above, the other issue with longer modules is that the module will have greater wind loading. This is an additional cost to the tracker and reduces its performance.

A feature of the present module is that we can increase the length in smaller segments than the 156 traditional cells size. This means that we can grow our module in much smaller increments without significantly increase the system costs. This allows the present module to increase the power of the module without inflicting a penalty on the tracker costs. In an example, the present technique allows taking an industry standard module, increase the area (length) by 7% and have a resulting power increase of 15% with the HD module design.

In an alternative example, the present technique also provides for desired module voltages. In an example, a way for cost reductions in installing systems is to reduce wiring and the associated costs of circuit protection and combiner boxes. In an example, the number of modules configured on single circuit (string) are limited by the DC voltage rating of the system. This is usually 600 VDC or 1000 VDC. Solaria's HD module is being designed for 1500 VDC. When going from 600V to 1000V to 1500V the system costs are reduced significantly. The number of modules in a string is calculated by determining the lowest temperature the module will experience in a location and then adding up the open circuit voltages of the modules. Thus a 1000V system with 46.1V modules in a location could be expected to have a maximum of 21 modules on a string (1000/46.1=21.7).

Usually as modules increase in size, the module voltage goes up. An example of this is that a 60 cell module would typically have an open circuit voltage of 38.4V. A 72 cell module made with the same cells would 46.1V. If the number of cells increased to make the module 15% more powerful than the voltage would increase to 53V. In this case the 1000V string would only be able to accommodate 18 modules (1000/53=18.9). This would result in huge costs increases for the system.

In an example, the present technique allows for cutting a cell into five (⅕) strips. The strips are then made into strings. In an example, six (6) strings are connected in parallel. In doing this, the voltage of the string is reduced by ⅙ while increasing the current by ⅙. This results in our 15% more powerful module having an open circuit voltage of 44.2V. This results in a 1000V string of 22 modules (1000/44.2=22.6). Thus we are able to significantly improve the system economics by providing both a more powerful module and more modules per string.

This benefit is dramatically improved when the module is rated for a 1500V system. In this case we can put up to 33 modules on a string. Usually this is an even number so it is shown as 32 modules.

In an example, large systems often face inefficiencies from soiling issues. That is, soil, snow, or other mechanical debris accumulates along edges of the solar module. In an example, uneven soiling is often an issue with large systems. This tends to accumulate on either end of the module. At the module is rotated during tracking the soiling tends to be trapped by the frame. For traditional module this has a huge effect. The way the strings are laid out means that the whole module is affected when the cells are shaded.

In conventional modules, the whole module is affected by the soiling on the tracker. By using variable diode protection we can limit the effect of soiling. In the case shown above, only 8.3% of the module is affected by the soiling. This has a huge impact on the energy performance of the system, which results in a huge advantage of our module design.

In an example, on a sunny day, typically 15% or more of the sun's energy is delivered through diffuse light. The sun's radiation can generally be broken up into two components, direct and diffuse light. Direct light is the light that travels directly from the sun to the module without any reflections. Diffuse light is usually the result of light that has had at least one reflection. Trackers are designed to capture as much of the direct light as possible without shadowing each other. However, trackers do shadow each other when it comes to diffuse light.

When a single axis tracker is horizontal (facing straight up), then the module can capture all the diffuse light. However when the tracker rotates away from the horizontal position, the bottom of the module will become shaded with regards to diffuse light from the modules on the tracker in front. The total illumination on the module will become non-uniform.

Similar to the soiling discussion above, the non-uniform light will cause all the cells to be limited in a traditional module. However, the present diode scheme will allow each section of module to operate at its maximum potential. Again this will result in improved energy yield, which is beneficial.

Further details of the present module that can overcome these limitations are described throughout the present specification and more particularly below.

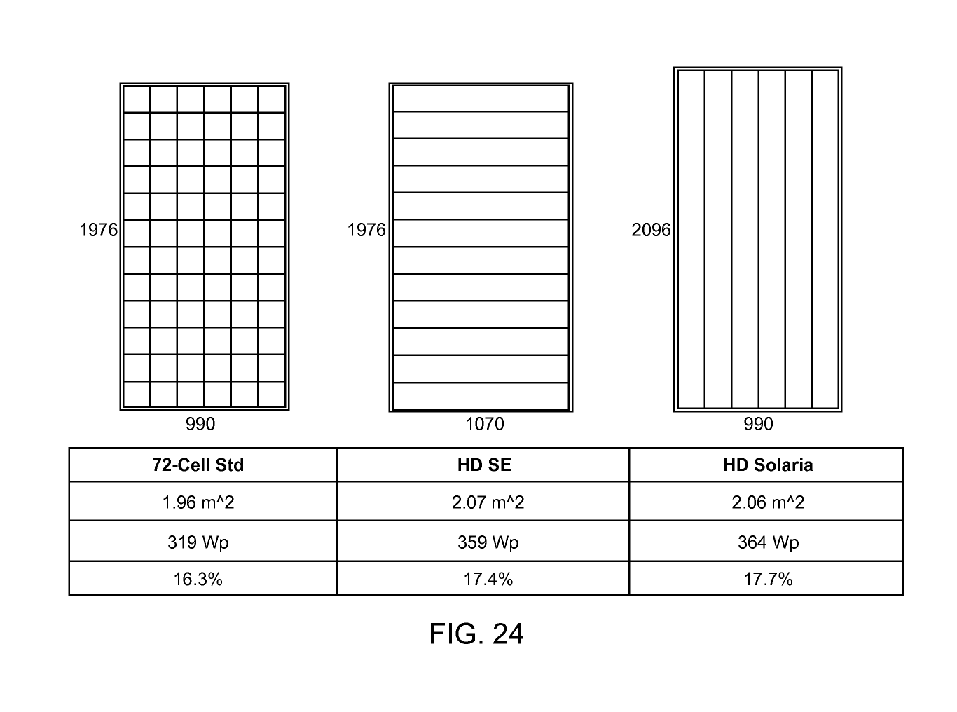

FIG. 24 is a simplified diagram illustrating a standard solar module, a high density solar module, and a high density module according to an example of the present invention, which is configured in vertical strips, as shown. As shown, a conventional module includes seventy two cells, and is configured in a checkerboard manner. A high density solar module, which has overlapped strips, and strings, is configured in a horizontal manner, as shown as HD SE. In an example of the present solar module, the strings are arranged in a vertical manner, extending from a bottom region, which is lowest to the ground, and an upper region. The present module is slightly longer in the vertical direction, and narrower in the width to accommodate solar tracker systems. The narrower the module the modules per tracker a single axis horizontal tracker can accommodate. More modules with more power make the price of the tracker go down relative to the energy it produces.

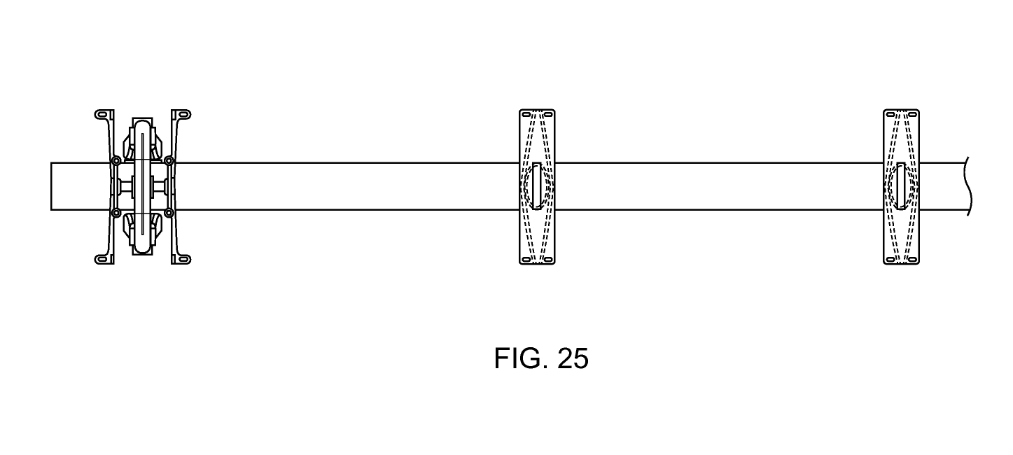

FIG. 25 is a simplified illustration of the aforementioned high density module configured on a solar tracker according to an example of the present invention. In an example, the present high density solar module can be configured in a vertical orientation along a torque tube of a solar tracker system. The narrower sized width allows for a tighter and improved packing factor, while the longer length provides for an improved overall power output. This provides for a lower cost system. If the module had become wider, the tracker would have to become wider and the system cost would increase.

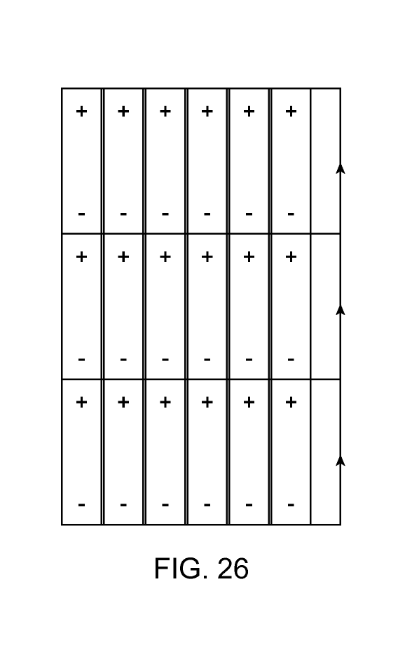

FIG. 26 is a simplified illustration of a solar module configured with diode protection for sixty nine strips in series, twenty three strip substrings, and three substrings in series for a seventy two cell module according to an example of the present invention. In an example, each of the three substrings is selected isolated via an individual diode device structure, and an overall equivalent diode characterizing the three diode devices.

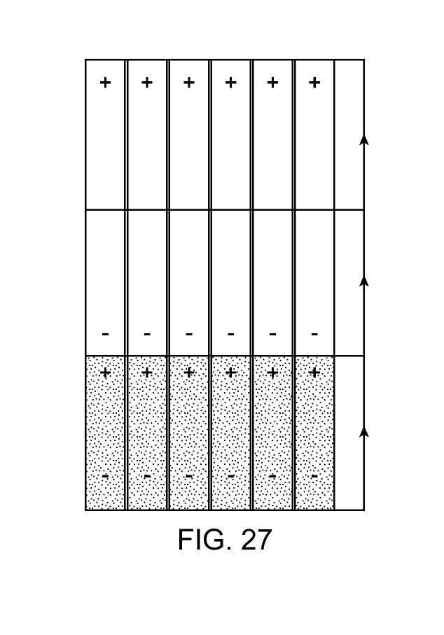

FIG. 27 is a simplified illustration of shading on a lower one third of a solar module according to an example of the present invention. As shown, shading in any of the lower substrings leads to bypassing the substring via the diode structure. One third of the solar module can be configured to traverse current from the third being blocked out.

In an example of the present invention a string configured along an upper and/or lower portion of the solar module can be assembled using a shorter string, than those located in the center region. Beneficial results have been observed using the shorter string in operating a solar tracker system with the present module. Further details of the present module can be found throughout the present specification and more particularly below.

In an example, the present module has a plurality of individual diode devices. Each of the plurality of individual diode device is coupled to each of the plurality of strips in each of the plurality of strings in each zone. In an example, at least one of the individual diode devices coupled to one of the plurality of strips to form a first edge string configured along the first edge of the array of solar cells, and characterized by a number of stripes N, where N is fewer in numbers than the plurality of strips forming a string within a center region of the array of solar cells. In an example, at least one of the individual diode devices coupled to one of the plurality of strips to form a second edge string configured along the second edge of the array of solar cells, and characterized by a number of stripes M, where M is fewer in numbers than the plurality of strips forming a string within a center region of the array of solar cells. Fewer strips leads to a shorter string region, leading to a smaller area of current rerouting upon shading of either the an upper or lower region of the solar module, which is often plagued with soiling limitations. Soiling can come from dirt or soil particles, snow, or other mechanical debris that can accumulate along edges of the solar module during use of the module on a tracker system.

In an example, each of the first edge string and the second edge string is characterized by an edge spatial width, the spatial width being narrower than a spatial width of the string configured within the center region of the solar array. Further details of the present module can be found throughout the present specification and more particularly below.

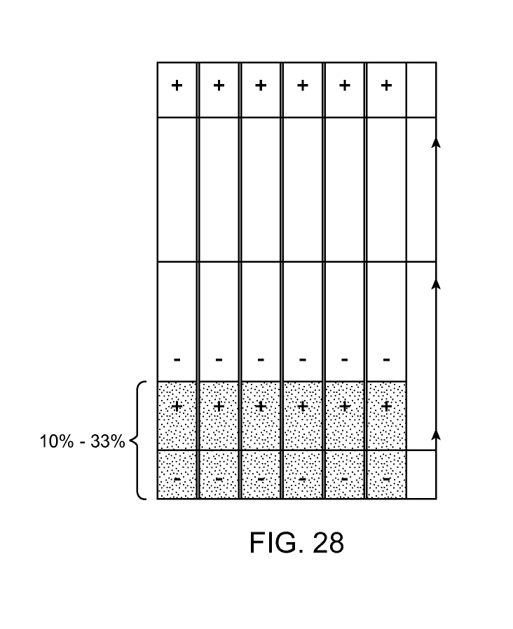

FIG. 28 is a simplified illustration of shading on a lower one third of a solar module using a shortened string on a lower portion of the solar module according to an example of the present invention. As shown, the shortened string can be provided along an upper region or lower region of the solar module. In an example, the shortened string has a length that is shorter than the longer strings in the center region, leading to reduced power loss upon shading.

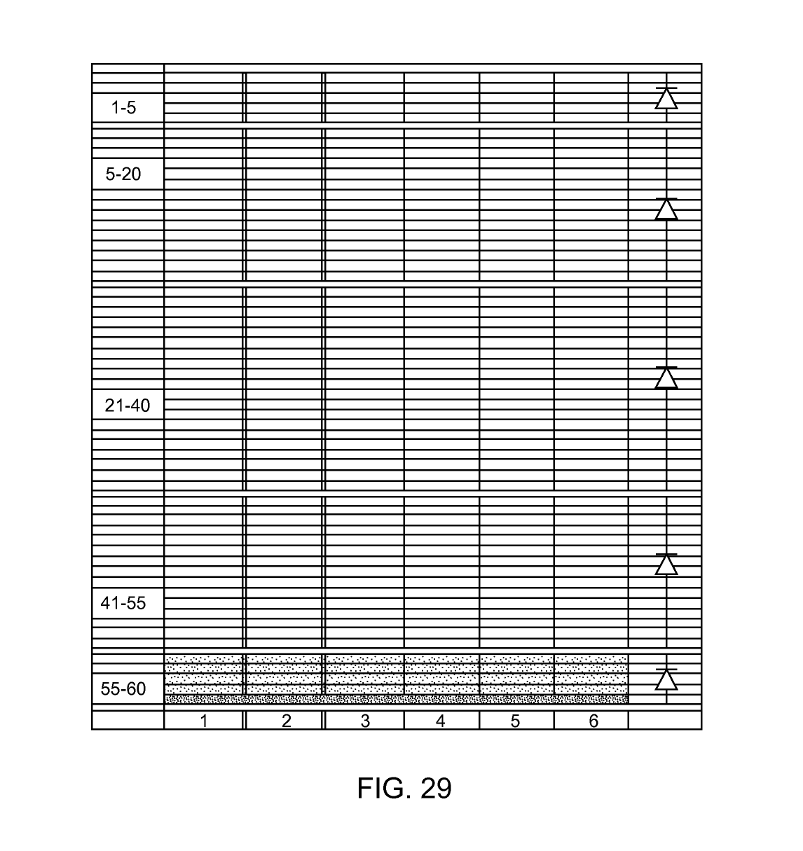

FIG. 29 is a simplified illustration of a diode protection configuration for a shortened string on a lower portion of the solar module according to an example of the present invention. In an example, the module has six strings in parallel and vertical alignment. Strips are shown for illustrative purposes on each of the ends but do not exist in the present module. In an example, strips 1-5 are configures as a shorter string along the upper region of the solar module. Strips 55-60 are configured as a shorter string along the lower region of the solar module. The shorter strings can be 1/10^{th} to ½ the length of the longer strings, which occupy the center region of the solar module. Typically modules soil more towards the edges of the module that are downward sloping. By providing individual shading protection for the first 50 mm to 150 mm of the top and or bottom of the module the shading from soiling has reduced effect on power.

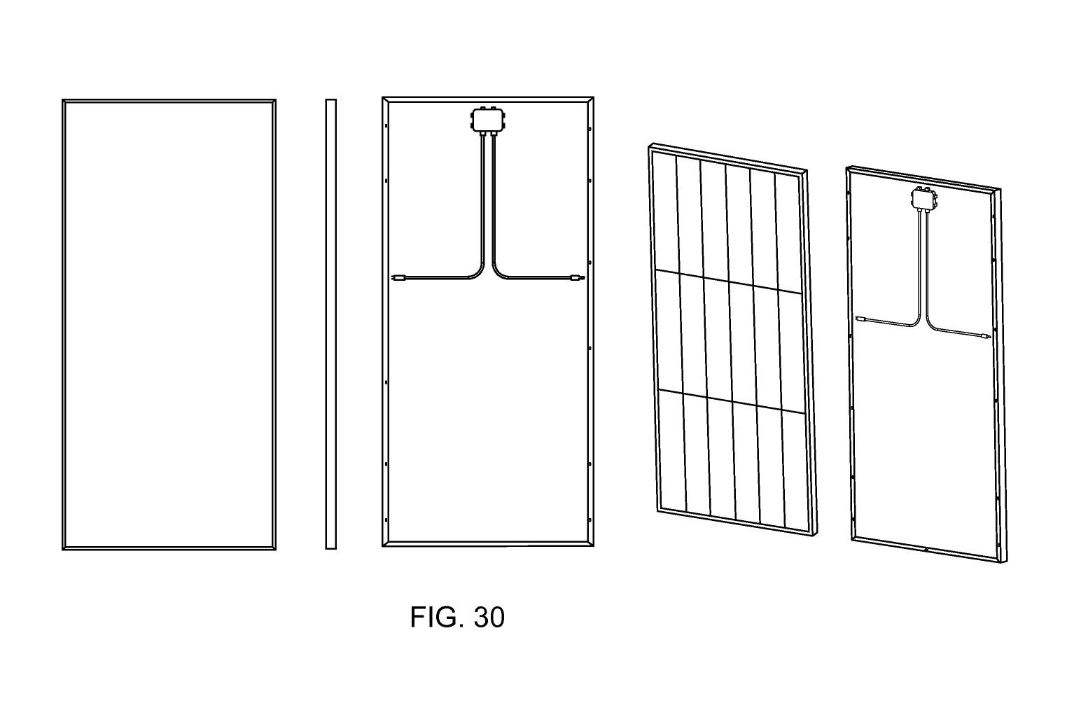

FIG. 30 is a simplified illustration of a solar module, including front view, side view, back view, perspective views according to examples of the present invention. As shown, the back view includes a junction box, that can include electronics to configured to the plurality of strings, diodes, and other features of the module.

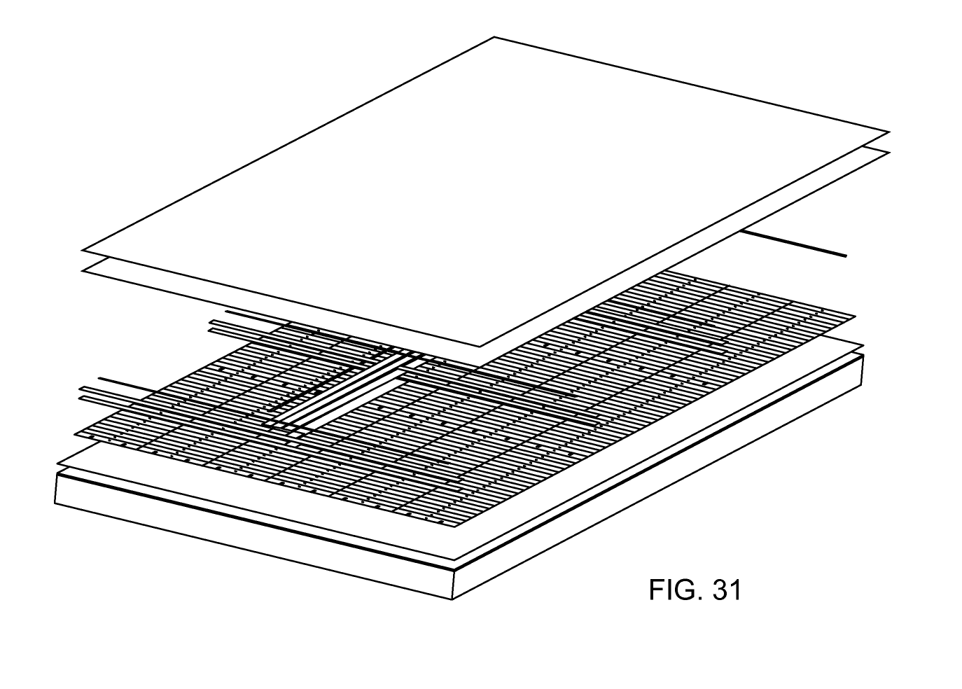

FIG. 31 is an expanded view of a solar module according to an example of the present invention. As shown, the solar module has a back sheet, a plurality of strings are sandwiched between an upper glass, and the back sheet. An arrangement of bus bars are configured along a center region of the solar module in vertical alignment with the length of the module. This arrangement allows all the diodes that protect the individual zones to be centrally located in the junction box.

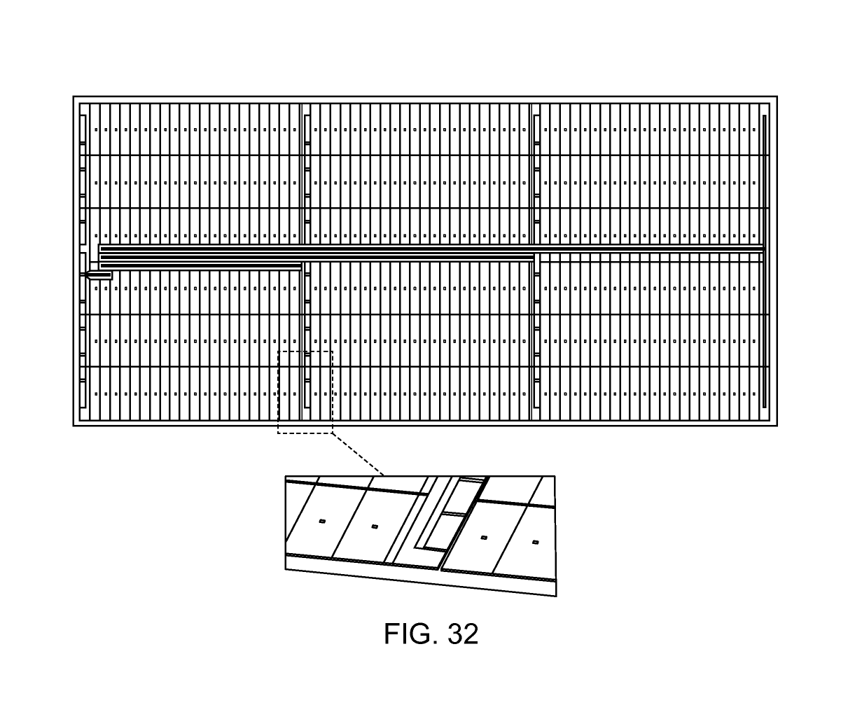

FIG. 32 is a simplified illustration of a back view, including an expanded region, of a solar module according to an example of the present invention. FIG. 32 depicts the electrical bussing interconnect used for the diode protection. In this embodiment the module is physically separated into 3 segments. The electrical interconnect between the segments is made through ribbon wire. The three physical segments also correspond to the three-diode protection regions. FIG. 32 also depicts bonding pads on the back of the cells. The bonding pads can also be used provide diode protection where the physical segments are different than the diode protection segments.

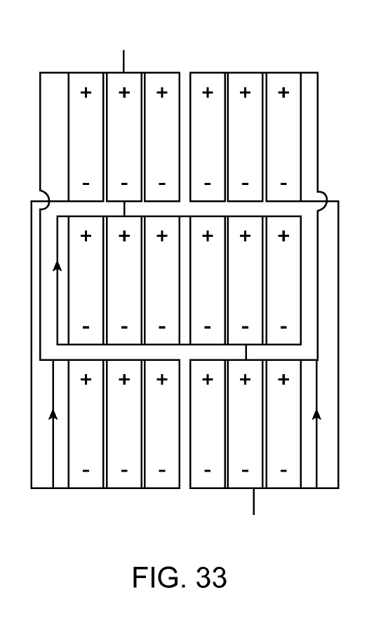

FIG. 33 is a simplified illustration of a different embodiment for the diode configuration for a solar module according to an example of the present invention. By electrically connecting PV strings in parallel from different physical locations it is possible to reduce the effects of non-uniform lighting that can occur with diffuse light collection on trackers.

It is understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A solar module apparatus comprising:
an array of solar cells configured together and having a length and a width, the length extending from a first edge to a second edge;
a plurality of zones dividing the array of solar cells, the plurality of zones numbered from 1 through 8, each of the plurality of zones being in series with each other;
a plurality of photovoltaic strings dividing each of the plurality of zones, each of the plurality of photovoltaic strings being in parallel with each other, the plurality of photovoltaic strings numbered from 2 to 8;
a plurality of photovoltaic strips forming each of the plurality of photovoltaic strings, the plurality of strips from 2 to 45, each of the plurality of strips being configured in a series arrangement with each other, each of the plurality of photovoltaic strips having a substantially similar width and substantially similar length;
a first bus bar and a second bus bar configured on each of the zones of the solar cells;
an equivalent diode device configured between the first bus bar and the second bus bar;
a plurality of individual diode devices, each of the plurality of individual diode device coupled to each of the plurality of strips in each of the plurality of strings in each zone;
at least one of the individual diode devices coupled to one of the plurality of strips to form a first edge string configured along the first edge of the array of solar cells, and characterized by a number of stripes N, where N is fewer in numbers than the plurality of strips forming a string within a center region of the array of solar cells;
at least one of the individual diode devices coupled to one of the plurality of strips to form a second edge string configured along the second edge of the array of solar cells, and characterized by a number of stripes M, where M is fewer in numbers than the plurality of strips forming a string within a center region of the array of solar cells;
whereupon one of the plurality of photovoltaic strips associated with one of the plurality of strings and associated with a first plurality of zones is shaded causing the plurality of strips (“Shaded Strips”) associated with the one of the strings to cease generating electrical current from application of electromagnetic radiation associated one of the strings, while a remaining plurality of strips, associated with the remaining plurality of strings, each of which generates a current that is substantially equivalent as the current while the Shaded Strips are not shaded, and the diode device between the first bus bar and the second bus bar for the plurality of strips is configured to turn-on to by-pass electrical current from the Shaded Strips through the diode device; and whereupon the electrical current that was by-passed traverses an equivalent diode device coupled to the plurality of strips associated with a second plurality of zones; and whereupon each of the first edge string and the second edge string is characterized by an edge spatial width, the spatial width being narrower than a spatial width of the string configured within the center region of the solar array.

2. The apparatus of claim 1 wherein the equivalent diode device is a sum of the individual diode devices coupled to each of the plurality of strips in each of the plurality of strings in each zone; the first edge string or the second edge string comprising a plurality of particles leading to soiling.

3. The apparatus of claim 1 wherein each of the plurality of strips comprises a thickness of photovoltaic material comprising a front bus bar and a back bus bar, the front bus bar being provided along a first edge region and the back bus bar being provided along a second edge region.

4. The apparatus of claim 1 wherein each of the plurality of strips comprises a thickness of photovoltaic material comprising a front bus bar and a back bus bar, the front bus bar being provided along a first edge region and the back bus bar being provided along a second edge region, each of the plurality of strips being associated with one of the plurality of strings, each of the plurality of strings associated with one of the plurality of strings being in an overlapped configuration to physically and electrically configure the string.

5. The apparatus of claim 1 wherein each of the plurality of strips comprises a thickness of photovoltaic material comprising a front bus bar and a back bus bar, the front bus bar being provided along a first edge region and the back bus bar being provided along a second edge region, each of the plurality of strips being associated with one of the plurality of strings, each of the plurality of strings associated with one of the plurality of strings being in an overlapped configuration to physically and electrically configure the string, each of the plurality of strips being configured from a silicon based mono-crystalline or multi-crystalline solar cell.

6. The apparatus of claim 1 wherein the array of solar cells configured to generate 300 to 450 Watts, each of the zones being configured to generate at least 70 Watts; each of the strips being configured to generate at least 0.8 Watt.

7. The apparatus of claim 1 further comprising a pair of substrate members configured to sandwich the array of solar cells, at least one of the substrate members being a transparent material.

8. The apparatus of claim 1 whereupon the array of solar cells is operable at a maximum power of the array of solar cells minus a power amount associated with the Shaded Strips.

9. The apparatus of claim 1 further comprising a power output equivalent to a maximum power rating less an amount equivalent to the string associated with the Shaded Strips.

10. The apparatus of claim 1 further comprising a power output equivalent to a maximum power rating less an amount equivalent to more the one of the strings associated with the Shaded Strips.

11. A solar module apparatus comprising:
an array of solar cells, the array of solar cells;
a plurality of zones dividing the array of solar cells, the plurality of zones numbered from 1 through 8, each of the plurality of zones being in series with each other;
a plurality of photovoltaic strings dividing each of the plurality of zones, each of the plurality of photovoltaic strings being in parallel with each other, the plurality of photovoltaic strings numbered from 2 to 8;
a plurality of photovoltaic strips forming each of the plurality of photovoltaic strings, the plurality of strips from 2 to 45, each of the plurality of strips being configured in a series arrangement with each other;
a first bus bar and a second bus bar configured on each of the zones of the solar cells;
an equivalent diode device configured between the first bus bar and the second bus bar;
a plurality of individual diode devices, each of the plurality of individual diode device coupled to each of the plurality of strips in each of the plurality of strings in each zone;
at least one of the individual diode devices coupled to one of the plurality of strips to form a first edge string configured along the first edge of the array of solar cells, and characterized by a number of stripes N, where N is fewer in numbers than the plurality of strips forming a string within a center region of the array of solar cells;
at least one of the individual diode devices coupled to one of the plurality of strips to form a second edge string configured along the second edge of the array of solar cells, and characterized by a number of stripes M, where M is fewer in numbers than the plurality of strips forming a string within a center region of the array of solar cells;
whereupon one of the plurality of photovoltaic strips associated with one of the plurality of strings and associated with a first plurality of zones is shaded causing the plurality of strips (“Shaded Strips”) associated with the one of the strings to cease generating electrical current from application of electromagnetic radiation associated one of the strings, while a remaining plurality of strips, associated with the remaining plurality of strings, each of which generates a current that is substantially equivalent as the current while the Shaded Strips are not shaded, and the diode device between the first bus bar and the second bus bar for the plurality of strips is configured to turn-on to by-pass electrical current from the Shaded Strips through the diode device; and
whereupon the electrical current that was by-passed traverses an equivalent diode device coupled to the plurality of strips associated with a second plurality of zones a plurality of electrical strings, each of the electrical stings being configured to form an equivalent strip provided by a plurality of strips from a plurality of stings connected in parallel to each other.

12. A solar module apparatus comprising:
a plurality of strings numbered from 2 to 8, each of the plurality of strings being configured in a parallel electrical arrangement with each other;
a plurality of photovoltaic strips forming each of the plurality of photovoltaic strings, the plurality of strips from 2 to 45, each of the plurality of strips being configured in a series arrangement with each other;
a first end termination configured along a first end of each of the plurality of strings, the first end termination being a first terminal;
a second end termination configured along a second end of each of the plurality of strings, the second end termination being a second terminal;
an equivalent diode device configured between the first end termination and the second end termination such that one of the plurality of photovoltaic strips associated with one of the plurality of strings when shaded causes the plurality of strips (“Shaded Strips”) associated with the one of the strings to cease generating electrical current from application of electromagnetic radiation, while a remaining plurality of strips, associated with the remaining plurality of strings, each of which generates a current that is substantially equivalent as an electrical current while the Shaded Strips are not shaded, and the equivalent diode device between the first terminal and the second terminal for the plurality of strips is configured to turn-on to by-pass electrical current through the equivalent diode device such that the electrical current that was by-passed traverses the equivalent diode device coupled to the plurality of strips that are configured parallel to each other;
a plurality of individual diode devices, each of the plurality of individual diode device coupled to each of the plurality of strips in each of the plurality of strings in each zone;
at least one of the individual diode devices coupled to one of the plurality of strips to form a first edge string configured along the first edge of the array of solar cells, and characterized by a number of stripes N, where N is fewer in numbers than the plurality of strips forming a string within a center region of the array of solar cells;
at least one of the individual diode devices coupled to one of the plurality of strips to form a second edge string configured along the second edge of the array of solar cells, and characterized by a number of stripes M, where M is fewer in numbers than the plurality of strips forming a string within a center region of the array of solar cells.

13. The solar module of claim 12 wherein the plurality of strings is provided in a zone, one zone is among a plurality of zones to form the solar module.

14. The solar module of claim 12 wherein the solar module is configured to generate from 100 to 600 Watts.

15. The solar module of claim 12 wherein the equivalent diode characterized as a plurality of individual diode devices each of which protects a string among the plurality of strings.

16. A solar module apparatus comprising:
a plurality of strings, each of the plurality of strings being configured in a parallel electrical arrangement with each other;
a plurality of photovoltaic strips forming each of the plurality of photovoltaic strings, the plurality of strips, each of the plurality of strips being configured in a series arrangement with each other;
a first end termination configured along a first end of each of the plurality of strings, the first end termination being a first terminal;
a second end termination configured along a second end of each of the plurality of strings, the second end termination being a second terminal;
an equivalent diode device configured between the first end termination and the second end termination such that one of the plurality of photovoltaic strips associated with one of the plurality of strings when shaded causes the plurality of strips (“Shaded Strips”) associated with the one of the strings to cease generating electrical current from application of electromagnetic radiation, while a remaining plurality of strips, associated with the remaining plurality of strings, each of which generates a current that is substantially equivalent as an electrical current while the Shaded Strips are not shaded, and the equivalent diode device between the first terminal and the second terminal for the plurality of strips is configured to turn-on to by-pass electrical current through the equivalent diode device such that the electrical current that was by-passed traverses the equivalent diode device coupled to the plurality of strips that are configured parallel to each other;
a plurality of individual diode devices, each of the plurality of individual diode device coupled to each of the plurality of strips in each of the plurality of strings in each zone; and
at least one of the individual diode devices coupled to one of the plurality of strips to form a first edge string configured along the first edge of the array of solar cells, and characterized by a number of stripes N, where N is fewer in numbers than the plurality of strips forming a string within a center region of the array of solar cells.

17. The apparatus of claim 16 wherein each of the photovoltaic strips provided in each string is arranged in serial connection via a tiled arrangement.

18. The apparatus of claim 16 further comprising at least one of the individual diode devices coupled to one of the plurality of strips to form a second edge string configured along the second edge of the array of solar cells, and characterized by a number of stripes M, where M is fewer in numbers than the plurality of strips forming a string within a center region of the array of solar cells.
